(19) United States
(12) Patent Application Publication
(10) Pub. No.: US 2012/0299045 A1
(43) Pub. Date: Nov. 29, 2012

(54) ORGANIC ELECTROLUMINESCENT DEVICE WITH INTEGRATED LAYER FOR COLOUR CONVERSION

(75) Inventors: Junyou Pan, Frankfurt am Main (DE); Susanne Heun, Bad Soden (DE)

(73) Assignee: Merck Patent GmbH Patents & Scientific Information, Darmstadt (DE)

(21) Appl. No.: 13/576,084

(22) PCT Filed: Jan. 3, 2011
(86) PCT No.: PCT/EP2011/000003

§ 371 Date: Jul. 30, 2012

(30) Foreign Application Priority Data
Jan. 30, 2010 (DE) 10 2010 006 280.4

(51) Int. Cl. H01L 33/50

(52) U.S. Cl. 257/98; 257/40; 257/E33.061

(57) ABSTRACT

The invention relates, inter alia, to an opto-electronic device having at least two electrodes (10, 15) and at least one light-emitting layer (EML) (12) arranged between the electrodes (10, 15), which comprises an electroluminescent organic material which emits light having a first wavelength spectrum, characterised in that at least one layer (1, 2, 5, 6) which comprises at least one colour converter is arranged between at least one of the at least one light-emitting layer (EML) and at least one electrode. The invention furthermore relates to a process for the production of an opto-electronic device of this type, and to the use of an opto-electronic device of this type as lamp or in a display.

The invention relates to an opto-electronic device having at least two electrodes and at least one light-emitting layer comprising an electroluminescent organic material arranged between the electrodes.

Electronic components based on organic semiconductors are easier to produce compared with components based on inorganic semiconductors and therefore offer the possibility of saving costs. However, components based on organic materials still do not have the performance capability of the corresponding inorganic equivalents and, in particular, exhibit a shorter lifetime. However, for example, organic light-emitting diodes are already employed on a large industrial scale in displays of mobile telephones.

Organic light-emitting diodes or organic light-emitting devices (OLEDs) are electronic components which are built up from organic, semiconducting materials arranged in thin layers one above the other and which are able to emit light under the influence of an electric field. In contrast to inorganic light-emitting diodes (LEDs), OLEDs do not require single-crystalline materials. They can therefore be produced relatively simply and thus inexpensively. A suitable choice of the light-emitting organic materials or combination with suitable filters enables various colours to be generated. OLEDs are therefore suitable for use, for example, in display screens for computers or mobile telephones. A further possible area of application is large-area room lighting.

OLEDs comprise a stack of thin layers applied to a suitable substrate. In a common arrangement, firstly a transparent anode is applied to a transparent substrate. A suitable transparent substrate is, for example, a glass sheet or a thin plastic film. The material used for the anode can be, for example, indium tin oxide (ITO). However, it is also possible to use a thin metal layer, for example comprising gold, as anode. The layer thickness here is selected to be sufficiently small that the anode is transparent to visible light. A hole-injection layer is usually applied to the anode. This layer on the one hand serves to lower the injection barrier for holes and on the other hand prevents diffusion of, for example, indium into the light-emitting layer.

A typical hole-injection layer consists, for example, of PEDOT/PSS (poly(3,4-ethylenedioxythiophene)/polystyrene sulfonate). A hole-transport layer (HTL) is then applied to the hole-injection layer. Common materials for the hole-transport layer are, for example, aromatic tertiary amines, as described in U.S. Pat. No. 4,539,507, or also tetraaryldiamines. A layer comprising the light-emitting organic material is then applied to the hole-transport layer. Besides a matrix, this layer may comprise the electroluminescent dye, usually in a proportion of about 5 to 10% by weight, or in some cases also completely consist of the dye. A suitable dye is, for example, aluminium tris(8-hydroxyquinoline), Alq₃. For example, organic light-emitting diodes have been developed in which the light-emitting layer essentially consists of a polymer carrying electroluminescent groups. The polymer here thus takes on both the function of a matrix and also of the electroluminescent dye. According to another embodiment, matrix and electroluminescent dye are formed from two different molecules. The matrix here can be formed by a polymer having semiconductor properties, or also by smaller molecules of lower molecular weight, which, however, do not exhibit electroluminescence, for example carbazole. The electroluminescent dye is then incorporated in this semiconductor matrix. The light-emitting layer may comprise a single electroluminescent dye and then essentially generate monochromatic light. In order, for example, to generate white light, however, it is also possible to dope the light-emitting layer with various electroluminescent dyes which emit light of different wavelength.

An electron-transport layer (ETL) is applied to the light-emitting layer. An electron-injection layer can also be applied to the electron-transport layer as protective layer and in order to reduce the injection barrier for electrons. Typical materials for this layer are lithium fluoride, caesium fluoride or LiQ (8-hydroxyquinolinato lithium). The cathode is then applied to the electron-injection layer. The cathode usually consists of a metal or alloy having a low electron work function, such as, for example, calcium, aluminium, barium, ruthenium or magnesium/silver alloys.

In addition to the layers already outlined, light-emitting diodes may also comprise further layers, for example buffer layers or also barrier layers for electrons or holes.

Electrons are injected into the electron-transport layer by the cathode after application of an electric field and migrate in the direction of the anode. Holes are injected into the hole-transport layer by the anode and migrate in the direction of the cathode. Holes and electrons meet in the light-emitting layer and recombine with formation of an exciton. The exciton may already represent the excited state of the dye molecule, or the decay of the exciton provides the energy for excitation of the dye molecule. The dye molecule returns to a ground state with emission of a photon. The colour of the emitted light depends on the energy separation between excited state and ground state. The colour of the light emitted by the organic light-emitting diode can therefore be modified specifically by variation of the dye molecules.

OLEDs exhibit a number of advantages compared with conventional lighting materials. Thus, for example, they are characterised by low energy consumption, uniform illumination, a large viewing-angle range, very short response times and favourable production costs. In addition, based on OLEDs transparent and flexible displays can be produced.

As further organic light-emitting component, organic light-emitting electro-chemical cells (OLECs) are being developed. These comprise two electrodes, between which a layer comprising a mixture of organic light-emitting substances and an ionic compound is arranged. The ions here are able to migrate to the electrodes. The first OLEC was described by Pei and Heeger, Science (95), 269, pp. 1086-1088. It comprised a mixture of a conjugated polymer (MEH-PPV), polyethylene oxide (PEO) and lithium trifluoromethanesulfonate as solid electrolyte. Furthermore, OLECs are known which comprise an ionic liquid as electrolyte. An OLEC of this type has been described, for example, by Nobuyuki Itohz in J. Electrochem. Soc. 156 (2) J37-J40 (2009). Furthermore, a planar OLEC has been described by G. Yu, Q. Pei, A. J. Heeger, Appl. Phys. Lett. 70 (1997) 934.

In the present application, the term polymer is taken to mean both polymeric compounds, oligomeric compounds, and dendrimers. The polymeric compounds according to the invention preferably have 10 to 10,000, particularly preferably 20 to 5000 and in particular 50 to 2000 structural units.

The oligomeric compounds according to the invention preferably have 3 to 9 structural units. The branching factor of the polymers here is between 0 (linear polymer, no branching points) and 1 (fully branched dendrimer).

The term “dendrimer” in the present application is intended to be taken to mean a highly branched compound built up from a multifunctional core, to which branched monomers are bonded in a regular structure, producing a tree-like structure. Both the core and also the monomers here can adopt any desired branched structures, which consist both of purely organic units and also organometallic compounds or coordination compounds. “Dendrimer” here is generally intended to be understood as described, for example, by M. Fischer and F. Võgtle (Angew. Chem., Int. Ed. 1999, 38, 885).

Both the weight- and number-average molecular weight of the polymers according to the invention are determined by gel permeation chromatography (GPC).

Finally, organic light-emitting field-effect transistors (OLEFTs) can also be mentioned as further light-emitting component. The structure of a field-effect transistor of this type is described, for example, by C. Cost et al., Appl. Phys. Lett. 85, p 1613 (2004). A field-effect transistor of this type comprises a gate electrode, on which a dielectric layer and a light-emitting layer are arranged. Furthermore, a source electrode and a drain electrode are provided, which are arranged on the opposite side of the dielectric layer to the gate electrode. Dielectrics (also known as insulators or non-conductors) are solid, liquid or gaseous substances which do not conduct electrical current, or only do so to a small extent. They have a high specific resistance of greater than 10¹⁰ Ωcm.

If the gate is arranged below the source and the drain electrode, the term “bottom gate” structure is used, while a structure in which the gate is arranged on the source and the drain electrode is called a “top gate” structure, provided that the substrate forms the lowermost layer. The light-emitting layer preferably comprises an ambipolar compound. This can be, for example, a mixture of n- and p-doped materials or also an intrinsically ambipolar compound, for example a conjugated polymer which can act both as hole conductor and also as electron conductor.

However, it is problematic in the production of display screens or also on use of, for example, OLEDs as room lighting that the various dyes available for electroluminescent organic components have different luminous intensity and a different lifetime. The colours of the visible wavelength spectrum can be produced per se by mixing the three primary colours red, green and blue. Since the corresponding dyes emit light of different luminance at a prespecified voltage between the electrodes, the luminance of the individual colours must be compensated, for example, by regulation of the electrode voltage. However, this also influences, for example, the lifetime of the dyes. The luminosity of an electroluminescent dye decreases continuously over the lifetime of an OLED or another electroluminescent component. The degree of reduction here is dependent on the type of dye and on the operating conditions of the OLED. If, for example, white light in room lighting is generated by mixing the three primary colours red, green and blue, a colour shift therefore occurs in the course of extended operation, since the three dyes age at different rates and their luminous intensity thus drops to different extents in the course of time.

US 2005/0253506 A1 describes an organic light-emitting diode in which firstly control elements, for example thin-film transistors, which define the area of individual pixels are arranged on a substrate. A layer which acts as colour filter is firstly applied to the control elements. This layer is planarised, so that it is not necessary to apply an interlayer in order to provide a planar surface for the build-up of the further components. An electrode which can be controlled by the control elements is then applied to the planarised colour filter. A layer stack comprising an electron-injection layer, an electron-transport layer, a light-emitting layer, a hole-transport layer and a hole-injection layer is in turn applied to the electrode. Finally, a second electrode is applied to the hole-injection layer. The light-emitting layer emits white light. The desired hue, for example red, green or blue, emitted by the OLED is generated by the colour filter.

US 2005/0260439 A1 describes an organic light-emitting diode which emits white light. The light-emitting diode comprises at least two electrodes, between which at least two organic electroluminescent materials are arranged. The two electroluminescent materials emit light with a different wave-length spectrum in each case. The organic light-emitting diode is arranged on a transparent substrate, where the electrode of the organic light-emitting diode arranged on the transparent substrate is likewise transparent. A layer comprising a photoluminescent compound is arranged on the opposite side of the substrate to the light-emitting diode. The photoluminescent compound is able to absorb light emitted by the light-emitting layer of the light-emitting diode. The photoluminescent compound then emits light having a second wavelength spectrum, whose maximum is shifted to greater wavelengths towards the maximum of the first wavelength spectrum. The second wavelength spectrum is selected so that the component overall emits white light.

US 2005/0206312 A1 describes a light-emitting component which generates white light. The component comprises an active layer which emits light of a first wavelength spectrum, and a passive layer which absorbs some of the light emitted by the active layer and emits light of a second wavelength spectrum which is shifted towards longer wavelengths. Active and passive layer are matched to one another in such a way that the component emits white light. The active layer is arranged between two electrodes, where one of the electrodes is transparent. The passive layer is arranged between the transparent electrode and a transparent substrate. The LED is built up from inorganic materials.

U.S. Pat. No. 6,696,177 B1 describes an organic light-emitting diode which emits white light. The organic light-emitting diode comprises a layer stack in which firstly a transparent anode is arranged on a transparent substrate. The transparent anode may be supplemented by a hole-injection layer. A hole-transport layer is arranged on the anode, and a light-emitting layer which is doped with a dye which emits blue light is arranged directly on the hole-transport layer. An electron-transport layer is in turn arranged on the light-emitting layer, and a cathode is arranged at the top on the electron-transport layer. The hole-transport layer, the electron-transport layer or both the electron-transport layer and the hole-transport layer may be doped with a dye which emits yellow light. If an undoped transport layer is arranged between the layer which emits blue light and the transport layer which is doped with the dye which emits yellow light, the intensity of the emitted yellow light decreases greatly with increasing layer thickness of the undoped transport layer, so that the light-emitting diode only emits blue light. The yellow dye in this arrangement is thus excited by the recombination of electrons and holes.

US 2004/0185300 A1 describes an organic light-emitting diode which emits white light. It comprises an anode, on which a hole-transport layer is arranged. A layer which emits blue light is arranged directly on the hole-transport layer. This layer comprises a matrix which is doped with a dye which emits blue light. Furthermore, the light-emitting layer is doped with an electron-transporting or hole-transporting material or a mixture of these materials in order to improve the light yield and the stability of the light-emitting diode. A cathode is arranged on the layer which emits blue light. The hole-transport layer or the electron-transport layer or both layers are doped with a compound which emits light in the yellow region of the spectrum. If an undoped layer is arranged between the layer which emits blue light and the electron- or hole-transport layer, the yield of white light decreases greatly with increasing thickness of the undoped layer, so that the light-emitting diode only emits blue light. In this arrangement, the yellow dye is thus also excited by recombination of holes and electrons. The white light emitted by the organic light-emitting diode can be utilised to provide a device, such as a display screen, which is able to display the entire colour spectrum. To this end, the organic light-emitting diode is provided with red, green and blue colour filters. The colour filters can be arranged on the substrate, which in this case must be transparent to light, integrated into the substrate or arranged on the upper electrode, in which case the latter must then be transparent to light.

US 2005/048311 A1 describes an organic light-emitting diode which emits white light. The organic light-emitting diode comprises an anode on which a hole-transport layer is arranged. A layer which emits blue light is arranged directly after the hole-transport layer. The layer which emits blue light is followed by an electron-transport layer, which is in turn followed by a cathode. The hole-transport layer comprises a matrix and a dye which emits yellow light, and a dye which emits red light. The hole-transport layer doped with the red or yellow dye may comprise a doped section and an undoped section, where the doped section immediately follows the layer which emits blue light. In combination with a red filter, the light-emitting diode is able to generate intense red light. The yellow and red dyes in this arrangement are thus excited by the recombination of electrons and holes.

Light-emitting diodes generate light of a certain wavelength or of a certain wavelength spectrum. In order, for example, to be able to display a figure on a display or in order to generate mixed colours or provide white light, light-emitting diodes which emit different colours, for example red, green and blue, can be arranged in a matrix, so that light-emitting diodes which emit light of different wavelength can be combined by a corresponding circuit. By the combination of different wavelength ranges, it is then possible, for example, to generate white light. In this case, however, the individual light-emitting diodes must be matched to one another very carefully in order to obtain the desired hue, for example white light. However, the materials available for organic light-emitting diodes exhibit a different light yield, meaning that the individual elements of the matrix must be addressed with a different voltage, depending on their light yield, for compensation. Since the organic material is subject to ageing processes, i.e. the luminous intensity of the diode decreases over its lifetime, the drop in luminosity must, in addition, be compensated, since otherwise colour shifts in the spectrum of the emitted light arise.

Instead of a combination of light-emitting diodes of different colours, it is also possible for a light-emitting diode which emits white light to be combined with a colour filter which partly absorbs the light emitted by the light-emitting diode and re-emits light of another wavelength. To this end, the light-emitting diode can also, for example, be coated with a thin layer of a medium for colour conversion, for example with a phosphor or another fluorescent and/or phosphorescent dye, where the degree of colour conversion, i.e. the colour of the light emitted by the light-emitting diode, can be adjusted through the amount of dye. In this way, it is possible to generate mixed colours from the light provided by the light-emitting diode and the light generated by the colour filter. In the arrangements known from the prior art, these colour filters are applied to the outside of the light-emitting diode arrangement.

It is disadvantageous in this procedure that at least one additional working step is necessary in which the colour filter layer is applied to the light-emitting diode. It is usually necessary also to apply a protective layer to the colour filter layer, which further increases the complexity and thus the production costs. Fluorescent dyes have hitherto only been employed for organic light-emitting diodes if the latter are employed as light source, for example for room lighting or as backlighting for liquid-crystal display screens, since structuring of the substrate is not necessary in this case. Substrate structuring of this type is necessary, for example, in a use for display screens, since the individual pixels therein emit different colours, for example red, green and blue.

The invention was therefore based on the object of providing an organic electroluminescent device which is simple to produce and in which the colour of the emitted light can be adjusted without major effort. In an embodiment, the organic electroluminescent device should also be suitable for use in display screens.

This object is achieved by means of an opto-electronic device having the features of Patent claim 1. The dependent patent claims relate to advantageous embodiments of the opto-electronic device according to the invention.

In contrast to the organic opto-electronic devices known to date, in particular the organic light-emitting diodes, a colour converter is not applied to the outside of the organic opto-electronic device in the case of the organic opto-electronic device according to the invention, but instead is integrated into the organic opto-electronic device in a layer arranged between the electrodes. The colour converter in the case of the organic opto-electronic device according to the invention is thus arranged in a region positioned between the electrodes. The active layer of the organic opto-electronic device emits light of a first wavelength, which is fully or partly absorbed by the colour converter and results in the emission of light of a second wavelength by the colour converter. Depending on the proportion of light emitted by the active layer which is absorbed by the colour converter, mixed colours can therefore be generated or the luminance of the emitted light can be adjusted.

In accordance with the invention, an organic opto-electronic device having at least two electrodes and at least one light-emitting layer arranged between the electrodes which comprises an electroluminescent organic material which emits light of a first wavelength or having a first wavelength spectrum is therefore provided, where at least one layer which comprises at least one colour converter is arranged between at least one of the at least one light-emitting layer and at least one electrode.

The organic opto-electronic device according to the invention exhibits per se the structure of known organic opto-electronic devices of this type. For the construction and production of the organic opto-electronic device, the person skilled in the art is therefore able to fall back on known devices and processes. In contrast to the known organic opto-electronic devices, however, the organic opto-electronic device according to the invention comprises, besides the light-emitting layer, at least one further layer which comprises one or more colour converters. The layer here may be built up completely from the colour converter or the layer may be doped with the colour converter.

The opto-electronic device according to the invention may comprise two electrodes, which, in accordance with an embodiment, form, for example, the cathode and the anode of an organic light-emitting electrochemical cell (OLEC). In accordance with the invention, at least one further layer which comprises the colour converter is then arranged between the light-emitting layer and the cathode or anode. Analogously to OLEDs, OLECs may comprise further layers selected from the group of hole-injection layers (HILs), hole-transport layers (HTLs), electron-transport layers (ETLs) and electron-injection layers (ElLs). These may enhance the performance of OLECs. Thus, for example, Shao et al. in Advanced Materials (2009), 21(19), 1972-1975, report on a polymeric OLEC having a long lifetime which comprises a crosslinked hole-transport layer (HTL). In a preferred embodiment of the present invention, the colour converter may be doped into at least one layer of the OLEC. Particularly preferred layers for this purpose are selected from the group consisting of HIL, HTL, EIL and ETL. Very particularly preferred layers which comprise the colour converter are selected from the group consisting of HIL and HTL, particular preference is given to HTL.

According to a further embodiment, the colour converter can be doped directly into the emission layer, in particular of the OLEC. The location of emission of the OLEC is typically restricted to a very small area in the vicinity of one of the two electrodes, and this area can be expanded by the described doping of the emission layer with the colour converter.

OLECs are, inter alia, characterised in that they comprise ionic materials. The ionic materials here may be small molecules, polymers, oligomers, polymeric blends or mixtures thereof.

The molecular weight of small molecules here is preferably less than 4000 g/mol, very preferably less than 3000 g/mol and very particularly preferably less than 2000 g/mol.

In a preferred embodiment of the present invention, the OLEC comprises an ion conductor, which is preferably selected from the group of polymeric materials, such as, for example, formulations based on perfluorosulfonic acid, polybenzimidazoles, sulfonated polyether ketones, sulfonated naphthalene-polyimides and polyethylene oxide (PEO). A very particularly preferred ion conductor in the sense of the present invention is polyethylene oxide (PEO).

The OLEC may also comprise at least one ionic organic electroluminescent compound of the general formula K⁺A⁻, where either K⁺ or A⁻ is an organic, emitting component. In a preferred embodiment of the present invention, the OLEC comprises 3, very preferably 2 and very particularly preferably 1 compound of the formula K⁺A⁻.

Typical compounds from the ionic materials are the ionic transition-metal complexes (iTMCs) (Rudmann et al., J. Am. Chem. Soc. 2002, 124, 4918-4921 and Rothe et al., Adv. Func. Mater. 2009, 19, 2038-2044). According to a further embodiment, however, the opto-electronic device according to the invention may also comprise three electrodes, which in this case form, for example, the gate and the source and the drain electrode of an organic light-emitting field-effect transistor. In this case, the layer comprising the colour converter may be arranged, for example, on the layer of the dielectric which forms the light-emitting layer. The gate electrode or the source and drain electrode is then arranged on the light-emitting layer.

According to a further embodiment, as depicted in FIG. 14 for the case of a bottom-gate OLEFT, a layer comprising a colour converter can be applied between the drain electrode and the gate electrode.

According to a further embodiment, the colour converter can be doped directly into the emission layer of the OLEFT. The site of emission of the OLEFT is typically restricted to a very small area between the source electrode or gate electrode, and this area can be expanded by the described doping of the emission layer with the colour converter.

According to a preferred embodiment, the opto-electronic device is in the form of an organic light-emitting diode (OLED).

The organic light-emitting diode according to the invention comprises a cathode and an anode, which are made from conventional materials. The cathode preferably comprises metals having a low work function, metal alloys, metal complexes or multilayered structures comprising various metals, such as, for example, alkaline-earth metals, alkali metals, main-group metals or lanthanoids (for example Ca, Ba, Mg, Al, In, Mg, Yb, Sm, etc.). In the case of multilayered structures, further metals which have a relatively high work function, such as, for example, Ag, may also be used in addition to the said metals, in which case combinations of the metals, such as, for example, Ca/Ag or Ba/Ag, are generally used.

The anode preferably comprises materials having a high work function. The anode preferably has a potential of greater than 4.5 eV vs. vacuum. Suitable for this purpose are on the one hand metals having a high redox potential, such as, for example, Ag, Pt or Au. On the other hand, metal/metal oxide combinations (for example Al/Ni/NiOₓ, Al/PtOₓ) may also be preferred. Preference is furthermore given to conductive, doped organic materials, in particular conductive doped polymers, for example polyaniline.

In order to facilitate the coupling-out of light, at least one of the electrodes must be transparent. A preferred structure uses a transparent anode. Preferred anode materials here are conductive mixed metal oxides. Particular preference is given to indium tin oxide (ITO) or indium zinc oxide (IZO).

A light-emitting layer comprising an organic semiconductor material and comprising an electroluminescent organic material is arranged between the electrodes. An electroluminescent organic material is taken to mean a dye which is converted into an excited state through the formation of an exciton, i.e. an electron/hole pair, and emits electromagnetic radiation, preferably in the visible region of the wavelength spectrum, in particular in a wavelength range from 380 to 780 nm, through recombination of the electron and hole. The electroluminescent material here is converted into a state of lower energy. The emission of light can take place both with retention of the spin and also with reversal of the spin as fluorescence or phosphorescence respectively. In the case of phosphorescence, the electronic transfer can take place from triplet states or also from states of even higher multiplicity (for example quintet) into an energetically lower electronic state of lower multiplicity. These dyes have a skeleton which can be traced back to a hydrocarbon. The dye may be built up merely from the skeleton which can be traced back to a hydrocarbon, where individual carbon or hydrogen atoms may also be replaced by heteroatoms or groups of heteroatoms, or also comprise one or more metal atoms to which organic groups are coordinated.

Thus, the light-emitting layer can be built up from a organic or organo-metallic material only which exhibits a high luminescence yield. A material of this type is, for example, Alq₃, which emits green light. However, the light-emitting layer can also be built up from a matrix which is able to transport both electrons and holes, but does not emit light itself. This matrix is then doped with small amounts of one or more electroluminescent dyes. The light-emitting layer can be formed from a polymer, which has optionally been derivatised with the electroluminescent dye and in this case forms the electroluminescent organic material directly. Derivatives of poly(p-phenylene-vinylene), for example, can be used in polymeric LEDs (PLEDs) of this type. However, it is also possible to use smaller molecules as matrix in the light-emitting layer. Illustrative smaller molecules which can be employed as matrix in the light-emitting layer are anthracene derivatives which are substituted by hydrocarbon radicals in positions 9 and 10, such as, for example, 9,10-diphenylanthracene and derivatives of these compounds. A suitable compound is, for example, 9,10-di(2-naphthyl)anthracene, where this skeleton may carry further substituents, for example alkyl radicals having 1 to 24 carbon atoms or aryl radicals having 5 to 20 carbon atoms. An illustrative compound from this class is 2-t-butyl-9,10-di(2-naphthyl)anthracene. Further suitable derivatives are described, for example, in U.S. Pat. No. 5,935,721 A.

The light-emitting layer comprises an electroluminescent organic material which emits light having a first wavelength spectrum or a first wavelength. The electroluminescent organic material used can per se be all electroluminescent dyes as are already known from use in OLEDs or other organic light-emitting electronic devices can be used per se. The electroluminescent dye can per se emit light of any desired wavelength, where the region of visible light and the ultraviolet region which is adjacent to the visible region at shorter wavelengths is preferred. Particular preference is given to the use of electroluminescent organic materials which emit light in the blue region of visible light (380 nm to 490 nm). A suitable blue dye is, for example, perylene and perylene derivatives in which the perylene skeleton is substituted by one or more substituents, such as, for example, alkyl radicals, aryl radicals or halogen atoms. A suitable derivative is, for example, 2,5,8,11-tetra-t-butylperylene. Another class of dyes which emit blue light are derivatives of distyrylarenes, such as distyrylbenzene and distyrylbiphenyl, as described, for example, in U.S. Pat. No. 5,121,029. A suitable compound of this type is, for example, [2-[4-[N,N-diarylamino]phenyl]vinyl]benzene and bis[2-[4-[N,N-diarylamino]phenyl]vinyl]biphenyls and derivatives thereof. Further suitable dyes which emit blue light are described in US 2005/0048311 A1.

Preferred dyes are selected from the class of the monostyrylamines, the distyrylamines, the tristyrylamines, the tetrastyrylamines, the styrylphosphines, the styryl ethers and the arylamines.

A monostyrylamine is taken to mean a compound which contains one substituted or unsubstituted styryl group and at least one, preferably aromatic, amine. A distyrylamine is taken to mean a compound which contains two substituted or unsubstituted styryl groups and at least one, preferably aromatic, amine. A tristyrylamine is taken to mean a compound which contains three substituted or unsubstituted styryl groups and at least one, preferably aromatic, amine. A tetrastyrylamine is taken to mean a compound which contains four substituted or unsubstituted styryl groups and at least one, preferably aromatic, amine. The styryl groups are particularly preferably stilbenes, which may also be further substituted. Corresponding phosphines and ethers are defined analogously to the amines. An arylamine or an aromatic amine in the sense of this invention is taken to mean a compound which contains three substituted or unsubstituted aromatic or heteroaromatic ring systems bonded directly to the nitrogen. At least one of these aromatic or heteroaromatic ring systems is preferably a condensed ring system, preferably having at least 14 aromatic ring atoms. Preferred examples thereof are aromatic anthracenamines, aromatic anthracenediamines, aromatic pyrenamines, aromatic pyrenediamines, aromatic chrysenamines or aromatic chrysenediamines. An aromatic anthracenamine is taken to mean a compound in which one diarylamino group is bonded directly to an anthracene group, preferably in the 9-position. An aromatic anthracenediamine is taken to mean a compound in which two diarylamino groups are bonded directly to an anthracene group, preferably in the 9,10-position. Aromatic pyrenamines, pyrenediamines, chrysenamines and chrysenediamines are defined analogously thereto, where the diarylamino groups on the pyrene are preferably bonded in the 1-position or in the 1,6-position.

Further preferred fluorescent dyes or dopants are selected from indenofluorenamines or indenofluorenediamines, for example in accordance with WO 06/122630, benzoindenofluorenamines or benzoindenofluorenediamines, for example in accordance with WO 2008/006449, and dibenzoindenofluorenamines or dibenzoindenofluorenediamines, for example in accordance with WO 2007/140847.

Examples of electroluminescent dyes from the class of the styrylamines are substituted or unsubstituted tristilbenamines or the dopants described in WO 2006/000388, WO 2006/058737, WO 2006/000389, WO 2007/065549 and WO 2007/115610. Distyrylbenzene and distyrylbiphenyl derivatives are described in U.S. Pat. No. 5,121,029. Further styrylamines are found in US 2007/0122656 A1.

Particularly preferred styrylamine dyes are:

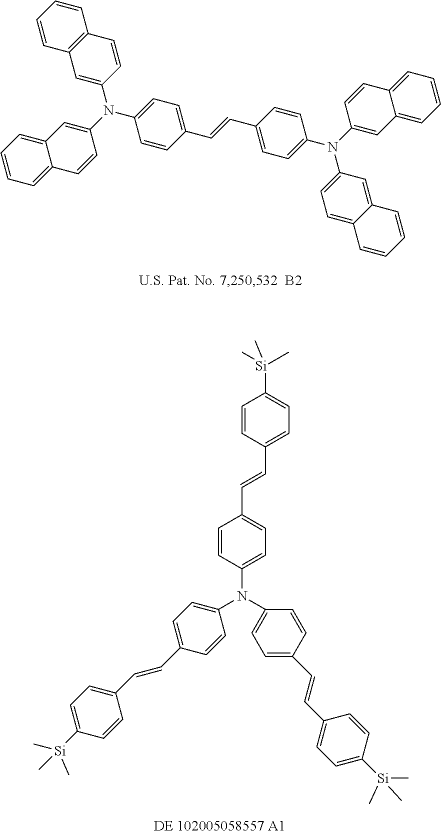

Particularly preferred triarylamine dyes are:

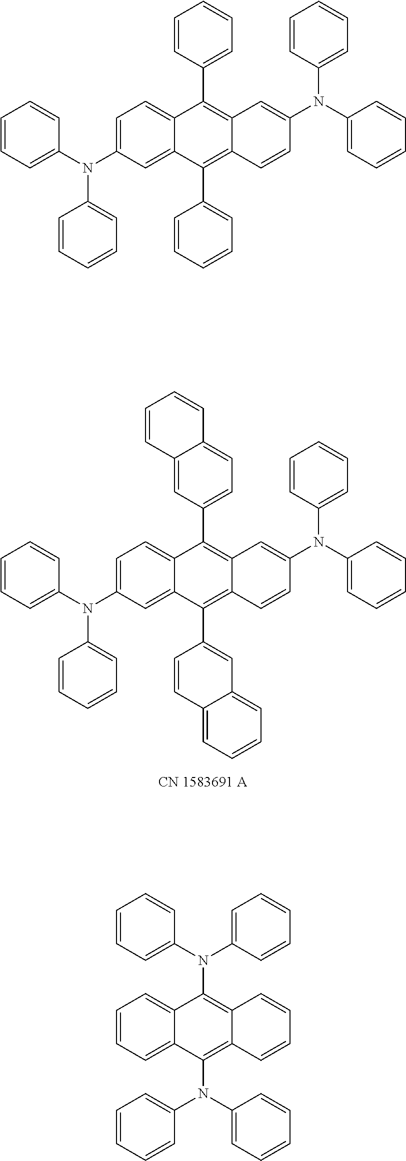

JP 08053397 A and U.S. Pat. No. 6,251,531 B1, derivatives in EP 1957606 A1 and US 2008 0113101 A1.

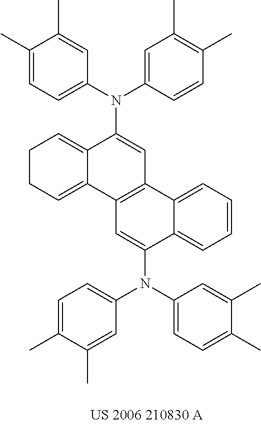

Further preferred electroluminescent dyes are selected from derivatives of naphthalene, anthracene, tetracene, periflanthene, indenoperylene, phenanthrene, perylene (US 2007/0252517 A1), pyrene, chrysene, decacyclene, coronene, tetraphenylcyclopentadiene, pentaphenylcyclopentadiene, fluorene, spirofluorene, rubrene, coumarin (U.S. Pat. No. 4,769,292, U.S. Pat. No. 6,020,078, US 2007/0252517 A1), pyran, oxazone, benzoxazole, benzothiazole, benzimidazole, pyrazine, cinnamic acid esters, diketopyrrolopyrrole, acridone and quinacridone (US 2007/0252517 A1).

Of the anthracene compounds, particular preference is given to 9,10-substituted anthracenes, such as, for example, 9,10-diphenylanthracene and 9,10-bis(phenylethynyl)anthracene. 1,4-Bis(9′-ethynylanthracenyl)benzene is also a preferred electroluminescent dye.

Blue electroluminescent dyes are preferably polyaromatic compounds, such as, for example, 9,10-di(2-naphthylanthracene) and other anthracene derivatives, derivatives of tetracene, xanthene, perylene, such as, for example, 2,5,8,11-tetra-t-butylperylene, phenylene, for example 4,4′-(bis(9-ethyl-3-carbazovinylene)-1,1′-biphenyl, fluorene, arylpyrenes, arylenevinylenes (U.S. Pat. No. 5,121,029, U.S. Pat. No. 5,130,603), derivatives of rubrene, coumarin, rhodamine, quinacridone, such as, for example, DMQA, dicyanomethylenepyran, such as, for example, DCM, thiopyrans, polymethine, pyrylium and thiapyrylium salts, periflanthene, indenoperylene. bis(azinyl)imine-boron compounds (US 2007/0092753 A1), bis(azinyl)methene compounds and carbostyryl compounds.

Further preferred blue electroluminescent dyes are described in C. H. Chen et al.: “Recent developments in organic electroluminescent materials” Macromol. Symp. 125, (1997) 1-48 and “Recent progress of molecular organic electroluminescent materials and devices” Mat. Sci. and Eng. R, 39 (2002), 143-222.

The light-emitting layer may be built up from a single layer. However, it is also possible for the light-emitting layer to comprise a plurality of layers, which may also have a different composition.

In accordance with the invention, at least one further layer which comprises at least one colour converter is arranged between the light-emitting layer which comprises the electroluminescent organic material and at least one of the electrodes.

In an embodiment of the opto-electronic device as OLED, this at least one layer preferably corresponds to a layer as is usually present in OLEDs, i.e., for example, an electron-transport layer, an electron-injection layer, a hole-injection layer or a hole-transport layer. However, the layer may also adopt the form of a buffer layer or barrier layer. Barrier layers of this type can be, for example, in the form of an electron-blocking layer, a hole-blocking layer or also an exciton-blocking layer. In accordance with the invention, a layer of this type comprises at least one colour converter.

According to an embodiment, the layer which comprises the at least one colour converter is arranged on the side of the at least one light-emitting layer which faces the cathode. The colour converter is then preferably arranged in the electron-injection layer and/or the electron-transport layer.

According to an embodiment, the material of the electron-transport layer also acts as hole-blocking layer and/or electron-blocking layer. This generates a very narrow light-emitting area.

According to an embodiment, at least one barrier layer is arranged between the at least one light-emitting layer and the at least one layer which comprises the at least one colour converter.

According to an embodiment, the barrier layer is in the form of a hole-blocking layer. The hole-blocking layer here is preferably arranged between the light-emitting layer and the layer which comprises the colour converter. The colour converter in this embodiment is preferably arranged in the electron-transport layer and/or the electron-injection layer.

According to an embodiment, the material of the hole-transport layer can simultaneously act as electron-blocking layer and/or as exciton-blocking layer.

According to a further embodiment, a barrier layer is provided which is in the form of an electron-blocking layer or exciton-blocking layer. In this embodiment, an electron-blocking layer and/or an exciton-blocking layer is thus arranged between the light-emitting layer and the layer comprising the colour converter. The colour converter in this embodiment is preferably provided in a hole-transport layer and/or a hole-injection layer.

In this embodiment, the barrier layer preferably does not comprise a colour converter.

A colour converter is taken to mean a compound which absorbs light of a first wavelength or from a first wavelength range and emits light of a second wavelength or in a second wavelength range which is shifted relative to the first wavelength or the first wavelength range. The second wavelength or the second wavelength range is preferably shifted to greater wavelengths compared with the first wavelength or the first wavelength range. However, it is also possible to achieve so-called “up conversion”. In this case, photons of relatively high energy are generated by simultaneous or sequential absorption of two or more photons of relatively low energy. Described mechanisms for this are two-photon absorption by molecules having a high two-photon absorption cross section, a nonlinear optical effect or multistep excitation processes.

Fluorescent dyes of this type are known, for example, as laser dyes, which usually have a high quantum yield for photoluminescence. In a preferred embodiment, the colour converter is electronically neutral, meaning that electron or hole transport towards the light-emitting layer is not disrupted. Furthermore, the colour converter should exhibit high photoluminescence, so that the essential part of the light emitted by the light-emitting layer is reemitted by the colour converter in another wavelength range.

Suitable fluorescent dyes which can be used as colour converters in the organic light-emitting diode according to the invention are, for example, coumarin and coumarin derivatives for emission in the blue to green-yellow spectral region, rhodamine and rhodamine derivatives for emission in the yellow to orange-red spectral region, stilbene and stilbene derivatives for emission in the blue spectral region, pyran derivatives, such as, for example, 4-dicyanomethylene-2-methyl-6-(p-dimethylaminostyryl)-4H-pyran (DCM), light-emitting organic salts, such as, for example, 3,3′-diethyloxacarbocyanine iodide (DOIC) or 3,3′-diethyl-4,4′,5,5′-dibenzothiatricarbocyanine iodide (DDTTCI). Further suitable laser dyes are described, for example, in the “Lambdachrome® Laser Dyes” handbook, Ulrich Brackmann (ed.), which is published by Lambda Physik AG, D-37079 Gõttingen, DE. However, it is also possible to use inorganic colour converters, as used, for example, in cathode ray tubes, luminescent displays or lamps. According to an embodiment, the inorganic colour converters are selected from the group of yttrium oxide, yttrium tantalite, barium fluoride, caesium fluoride, bismuth germinate, zinc gallate, calcium magnesium pyrosilicate, calcium molybdate, calcium chlorovanadate, barium titanium pyrophosphate, metal tungstates, cerium- or bismuth-doped phosphorus, thallium-doped sodium iodide, doped caesium iodide, pyrosilicates which are doped with rare-earth metals, and the halides of the lanthanides.

According to a preferred embodiment, the colour converter used is a phosphorescent substance having a narrow emission spectrum. This embodiment is particularly suitable for use of the OLED according to the invention in display screens. Phosphorescent substances of this type can be, for example, compounds which include metals of the rare earths. Instead of bands, these compounds exhibit characteristic luminescence spectra which are caused by transitions in the 4fn shell, which is very strongly screened by the 5d and 6s electrons. These phosphorescent substances preferably exhibit absorption at a wavelength of greater than 380 nm and can be selected, for example, from the group of Y₂O₃:Sm, Y₂O₃:Eu, Y₂O₃:Dy and Y₂O₃:Ho, as described by Lyuji Ozawa and Minoru Itoh in Chem. Rev. Vol 103 pp 3836 (2003) and the references cited therein. Further preferred phosphorescent substances can be selected, for example, from the group of ZnS:Cu,Al, ZnS:Cu,Au,Al, Y₂O₂S:Eu, Y₂O₂S:Eu, Zn₂SiO₄:Mn, (KF,MgF₂):Mn, (KF,MgF₂):Mn, MgF₂:Mn, (Zn,Mg)F₂:Mn, Zn₂SiO₄:Mn,As, Gd₂O₂S:Tb, Y₂O₂S:Tb, Y₃Al₅O₁₂:Tb, Y₃(Al,Ga)₅O₁₂:Tb, Y₂O₃:Eu, InBO₃:Tb, InBO₃:Eu, Y₂SiO₅:Tb.

According to a further preferred embodiment, the colour converter is a phosphorescent compound having a broad emission spectrum. This embodiment is particularly suitable for lighting applications. To this end, the colour converter can be selected, for example, from the group of YAG:Ce, ZnS:Ag+(Zn, Cd)S:Cu, (Zn, Cd)S:Ag, (Zn, Cd)S:Cu, (Zn, Cd)S:(Cu, Cl), ZnS:Ag+(Zn, Cd)S:Cu, Y₂O₂S:Tb, (Zn, Cd)S:Cu, Cl+(Zn, Cd)S:Ag, Cl, ZnS:Ag+ZnS:Cu(or ZnS:Cu,Au)+Y₂)₂S:Eu, InBO₃:Tb+InBO₃:Eu+ZnS:Ag, InBO₃:Tb+InBO₃:Eu.

According to a preferred embodiment, the colour converter is in the form of nanoparticles. Materials which can be employed for the nanoparticles are, for example, the inorganic compounds mentioned above. The nanoparticles preferably have a diameter of less than 100 nm, preferably less than 50 nm, further preferably less than 30 nm and particularly preferably less than 20 nm. The nanoparticles can be produced by standard chemical methods, for example as colloid, by cluster formation, by sol-gel processes or by electrochemical processes, as well as physical processes, such as molecular beam epitaxy, sputtering or aggregation of monomers in the gas phase. The production of nanoparticles by chemical methods can be carried out, for example, by precipitation in the presence of inhibiting compounds. Sol-gel processes and reactions in microemulsion are preferred processes for the production of fluorescent nanoparticles. Regarding the individual processes, reference can be made, for example, to the review article by Harish Chander in Materials Science Engineering R 49 (2005) 113-155. Further examples of nanomaterials which can be used as colour converters are YVO₄:Bi³⁺,Eu³⁺, which can be prepared by the wet-chemical processes described by Ogata et al., in Kidorui (09), 54, pp 56-57; Ca₁₂Al₁₄O₃₃(Ca₁₂A₁₇), nanomaterials which are co-doped with Er³⁺/Yb³⁺ ions and can be prepared by combustion syntheses, as described by Joschi et al. in J. Appl. Phys. (09), 105, pp. 123103/1-123103/7, Dy³⁺:GAG nanoparticles, which can be produced by solvothermal processes, as described by N. Y. Raju et al. in J. Alloys Compd. (09), 481, pp. 730-734 and in Opt. Mater. (Amsterdam, Neth.) (09), 31, pp. 1210-1214. Nanoparticles based on rare-earth metals can be produced, for example, by sintering a mixture of an inorganic salt and a precursor compound of the nanomaterial under the action of microwaves, as described in US 2009/140203. Nanomaterials having a composition of Ba₁₋ₓMₓAl₁₂O₁₉:Eu (M=Ca and Sr) (x=0.1-0.5) can be prepared by combustion processes, as described by J. Lumin. (09), 129, pp. 691-695. Eu-activated ZnMgAl₁₀O₁₇ nanoparticles can be produced by thermal processes using urea as template, as described in J. Alloys Compd. (09), 475, pp 343-346. Nanoparticles of the formula Y₂O₃:Eu³⁺ can be produced by a modified thermal process, as described in J. Appl. Phys. (09), 105, pp. 064302/1-064302/6.

According to an embodiment which uses a colour converter which can be activated by upconversion, nanomaterials of the formula NaYF4:Yb, Ln, for example, can be used, where Ln is selected from the group of Er, Ho and Tm, as described in der WO2009/046392. Up-conversion using organic materials is also possible, as described in WO 2006/008068.

In the opto-electronic device according to the invention, the colour converter is provided in a layer which is arranged between the light-emitting layer and an electrode. The layer used is preferably a layer which is already provided in corresponding devices from the prior art, meaning that devices of this type are only modified by the additional provision of the colour converter in one of the layers.

Since the colour converter is integrated, for example, into one of the layers of the organic light-emitting diode, the production of light-emitting diodes of this type is significantly simplified, since, in the simplest embodiment, the colour converter need only be added to the material of the relevant layer during production of the organic light-emitting diode. The production of the organic diode therefore follows the conventional production process, without it being necessary to apply an additional layer or specifically to seal the layer comprising the colour converter in order to protect it against environmental influences.

The organic light-emitting diode can be applied to conventional substrates, i.e., for example, glass, plastic films, semiconductor materials, such as silicon wafers, ceramic materials or also polished metal surfaces.

The substrate can be rigid or flexible. It can be transparent, translucent, opaque or reflective. The materials used can be glass, plastic, ceramic or metal foils, where plastic and metal foils are preferably used for flexible substrates. However, it is also possible to employ semiconductor materials, such as, for example, silicone wafers or circuit-board materials, in order to simplify the generation of conductor tracks. Other substrates can also be employed.

The glass used can be, for example, sodium bicarbonate-lime glass, Ba- or Sr-containing glass, lead glass, aluminium silicate glass, borosilicate glass, Ba-borosilicate glass or quartz.

Plastic plates can consist, for example, of polycarbonate resin, acrylic resin, vinyl chloride resin, polyethylene terephthalate resin, polyimide resin, polyester resin, epoxy resin, phenolic resin, silicone resin, fluorine resin, polyether sulfide resin or polysulfone resin.

For transparent films, use is made, for example, of polyethylene, ethylene-vinyl acetate copolymers, ethylene-vinyl alcohol copolymers, polypropylene, polystyrene, polymethyl methacrylate, PVC, polyvinyl alcohol, polyvinyl butyral, nylon, polyether ether ketone, polysulfone, polyether sulfone, tetra-fluoroethylene-perfluoroalkyl vinyl ether copolymers, polyvinyl fluoride, tetrafluoroethylene-ethylene copolymers, tetrafluoroethylene-hexafluoropropylene copolymers, polychlorotrifluoroethylene, polyvinylidene fluoride, polyester, polycarbonate, polyurethanes, polyimide or polyether-imide.

According to an embodiment, the substrate can be provided with a hydrophobic layer.

The substrates are preferably transparent. It is also possible to use materials other than those mentioned here. Suitable materials are known to the person skilled in the art.

The organic light-emitting device, in particular an OLED, can be integrated into conventional electronic components or also employed in a large area as lighting means. To this end, organic light-emitting device can be provided with a voltage supply and optionally control electronics. The voltage supply of the two electrodes takes place here via conventional supply lines.

According to an embodiment, the colour converter is selected so that the colour converter absorbs light from the first wavelength spectrum which is emitted by the electroluminescent organic material, and emits visible light having a second wavelength spectrum. According to an embodiment, this second wavelength spectrum can be shifted towards greater wavelengths compared with the first wavelength spectrum. The colour converter in this embodiment is selected so that it exhibits an absorption maximum which is in the emission spectrum of the electroluminescent organic material or substantially corresponds thereto, so that the highest possible light yield is achieved. The colour converter therefore does not have to be present in a layer which is directly adjacent to the light-emitting layer. It is thus also possible for a further layer, for example a buffer layer or preferably a barrier layer, to be arranged between the light-emitting layer which comprises the electroluminescent organic material and the layer which comprises the colour converter.

Thus, according to an embodiment, at least one hole-barrier layer, which does not comprise a colour converter, is arranged between the at least one light-emitting layer and an electron-transport layer which comprises the colour converter.

According to a further embodiment, an electron-barrier layer is arranged between the at least one light-emitting layer and a hole-transport layer which comprises the colour converter.

If further layers are arranged between the light-emitting layer and the layer which comprises the colour converter, these should be transparent in the wavelength spectrum emitted by the electroluminescent material. It is thus not necessary for the colour converter to be concentrated in a region of the organic light-emitting diode in which energy is liberated by the recombination of electrons and holes. The colour converter may therefore also be distributed homogeneously in a relatively thick layer, enabling the quantum yield of the light absorbed by the colour converter or emitted by the electro-luminescent organic material to be increased.

The electroluminescent organic material is preferably selected in such a way that the emitted light, which corresponds to the first wavelength spectrum in the sense of the invention, is in the blue region, in particular in a wavelength range from 380-490 nm. Blue light or the adjacent ultraviolet region has relatively high energy, meaning that the entire region of visible light can be made available through the choice of suitable colour converters. In addition, electroluminescent organic compounds are now known which emit in the blue region of visible light and which on the one hand have a high light yield and on the other hand a lifetime which is suitable for practical applications of the electronic components, without a significant reduction in the luminosity having to accepted at the same time.

As already explained, the colour converter can be selected per se in any desired manner, so that the light emitted by the electroluminescent organic material can be converted into light of the desired colour and intensity through the choice of the colour converter and the concentration of the colour converter. The wavelength of the light emitted by the colour converter can therefore be selected per se as desired and is ultimately dependent on the compound or substance employed as colour converter.

According to a first embodiment, the colour converter emits light in the infrared region, i.e. in the range from 780 nm to 1 mm.

In particular for use in displays, it is preferred in accordance with an embodiment for the second wavelength spectrum emitted by the colour converter or the second wavelength to be selected in the red region of visible light, preferably in the range from 780 to 650 nm.

According to a further embodiment, it is provided that the second wavelength spectrum emitted by the colour converter is selected in the green region of visible light, preferably in the range from 560 to 490 nm.

Through a combination of the three primary colours red, green and blue, all colours of the visible region can be displayed. The component of blue light can be formed directly by the blue light emitted by the electroluminescent organic material. However, it is also possible for a colour converter to be provided which emits light in the blue region of visible light, for example in the range from 490 to 380 nm.

The colour converter can per se be present in any layer which is arranged between the light-emitting layer comprising the electroluminescent organic material and one of the electrodes in a conventional organic light-emitting diode. The colour converter may be present in just one of the layers. However, it is also possible for a plurality of layers of the organic light-emitting diode to comprise a colour converter. The colour converter present in various layers may be the same. However, it is also possible for different colour converters to be provided in different layers of the organic light-emitting diode. In this way, it is possible, for example, to provide an organic light-emitting diode in which the front and back of the organic light-emitting diode emit light of different colour.

According to an embodiment of the organic light-emitting diode according to the invention, it is provided that the organic light-emitting diode comprises a hole-transport layer, where the hole-transport layer comprises the colour converter.

Materials which are conventional per se can be used as material for the hole-transport layer.

Suitable materials for the hole-transporting layer are, for example, triazole derivatives, as are described in U.S. Pat. No. 3,112,197, oxazole derivatives, as are known from U.S. Pat. No. 3,257,203, oxadiazole derivatives, as are shown, for example, in U.S. Pat. No. 3,189,447, imidazole derivatives, as are described in JP-B-37-16096 and pyrazoline and pyrazolone derivatives, as are described in U.S. Pat. No. 3,180,729. Also suitable are phenylenediamine derivatives, for example from U.S. Pat. No. 3,615,404, arylamine derivatives from U.S. Pat. No. 3,567,450, amino-substituted chalcone derivatives from U.S. Pat. No. 3,526,501, or also styrylanthracene derivatives, as are known from JP-A-56-46234. Also suitable are polycyclic aromatic compounds, as are described in EP 1 009 041 or also polyarylalkane derivatives, as are described, for example, in U.S. Pat. No. 3,615,402. Further suitable materials are, for example, fluorenone derivatives, as are known from JP-A-54-110837, hydrazone derivatives, as are known from U.S. Pat. No. 3,717,462, and stilene derivatives, as are known from JP-A-61-210363., Further suitable compounds are silazane derivatives, for example from U.S. Pat. No. 4,950,950, polysilanes, as from JP-A-2-204996, aniline copolymers, as from JP-A-2-282263, thiophene oligomers, polythiophenes, poly(N-vinyl-carbazole) (PVK), polypyrroles, polyanilines and further copolymers, such as, for example, PEDOT/PSS. Suitable hole-transporting materials are also porphyrin compounds, as described, for example, in JP-A-63-2956965, aromatic dimethylidene-type compounds, or also carbazole compounds, such as, for example, CDBP, CBP, mCP.

Inorganic compounds, such as p-type Si and p-type SiC, can also be used as hole-transporting materials.

Suitable compounds are also, for example, aromatic tertiary amines. An aromatic tertiary amine is taken to mean a compound which contains at least one trivalent nitrogen atom which is only bonded to carbon atoms, where at least one of the carbon atoms is part of an aromatic ring. Suitable aromatic tertiary amines can also be, for example, arylamines, such as monoarylamines, diarylamines or triarylamines, or also a polymeric arylamine. The aryl groups may also be further substituted and have, for example, vinyl radicals as substituents. Suitable triarylamines are described, for example, in U.S. Pat. No. 3,180,730. Other suitable materials are known, for example, from U.S. Pat. Nos. 3,567,450 and 3,658,520.

Aromatic tertiary amines which contain at least two units of aromatic tertiary amines are preferably employed in the hole-transport layer. Compounds of this type are described, for example, in U.S. Pat. Nos. 4,720,432 and 5,061,569. The hole-transport layer may be built up from only one compound. However, it is also possible to produce the hole-transport layer from a mixture of different compounds, for example from a mixture of aromatic tertiary amines. Suitable compounds are, for example, 1,1-bis(4-di-p-tolylaminophenyl)cyclohexane, 1,1-bis(4-di-p-tolylaminophenyl)-4-phenylcyclohexane, N,N,N-tri(p-tolyl)amine, N,N,N′,N′-tetra-p-tolyl-4,4′-diaminobiphenyl, N,N,N′,N′-tetra-2-naphthyl-4,4′-diaminobiphenyl or N-phenylcarbazole.

Particular preference is given to the following triarylamine compounds, which may also be substituted:

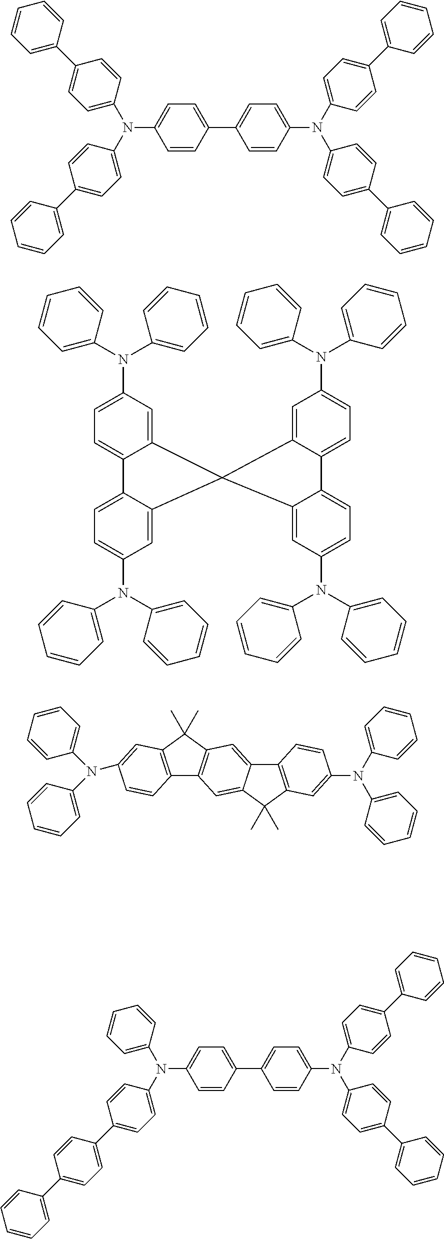

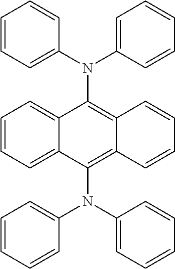

Hole-transporting layers may be intrinsic (undoped) or doped. Doping may improve the conductivity. Examples of intrinsic materials are α-NPB and TPD. An example of a doped layer is m-MTDATA doped with F₄-TCNQ, in accordance with US 2003-0230980.

Hole-transporting layers may be crosslinked, for example N⁴,N⁴′-di(naphthalen-1-yl)-N⁴,N⁴′-bis(4-vinylphenyl)biphenyl-4,4′-diamine has a low temperature for the crosslinking reaction. The dopant employed can also be fullerene derivatives, for example {6}-1-(3-(methoxycarbonyl) propyl)-{5}-1-phenyl-[6,6]-C61 in accordance with US 2008/0054783 A1. Further fullerene derivatives are described in Wang et. al., Applied Physics Lett. 80(20), (2002), 3847-3849.

The said compounds merely represent a very small selection of possible compounds. Besides the said compounds, however, all other compounds known as hole conductors to the person skilled in the art can also be employed.

According to a further embodiment, the organic light-emitting diode comprises a hole-injection layer where the hole-injection layer comprises the colour converter. The hole-injection layer can likewise be produced from all materials which are known to the person skilled in the art for use as hole-injection layer in organic light-emitting diodes. Thus, for example, it is possible to use triazole derivatives, for example from U.S. Pat. No. 3,112,197, oxazole derivatives, for example from U.S. Pat. No. 3,257,203, oxadiazole derivatives, such as from U.S. Pat. No. 3,189,447, imidazole derivatives, as in JP 37-16096, imidazolones, imidazolethiones, or also tetrahydroimidazoles. For the hole-injection layer, polyarylalkane derivatives, such as from U.S. Pat. No. 3,615,402, pyrazoline and pyrazolone derivatives, as described in U.S. Pat. No. 3,180,729 and U.S. Pat. No. 4,278,746, phenylenediamine derivatives, such as from U.S. Pat. No. 3,615,404, arylamine derivatives, such as from U.S. Pat. No. 3,567,450, amino-substituted chalcone derivatives, such as from U.S. Pat. No. 3,526,501, or also styrylanthracene derivatives, as described in JP 54 110837, are furthermore also suitable. Also suitable are, for example, hydrazone derivatives, as described, for example, in U.S. Pat. No. 3,717,462, acylhydrazones, stilbene derivatives, silazane derivatives, as described in U.S. Pat. No. 4,950,950, or also polysilane compounds, PVK and other electrically conductive macromolecules. Also suitable are aniline-based copolymers, for example from JP 2-282263, electrically conducting, macromolecular thiophene oligomers, such as from JP 1-211399, PEDOT:PSS (spin-coated polymer), plasma-deposited fluorocarbon polymers, as described in U.S. Pat. No. 6,127,004, U.S. Pat. No. 6,208,075 and U.S. Pat. No. 6,208,077, porphyrin compounds, as known, for example, from U.S. Pat. No. 4,720,432, aromatic tertiary amines and styrylamines, triphenylamines of the benzidine type, triphenylamines of the styrylamine type, triphenylamines of the diamine type. Arylamine dendrimers can also be used, as can phthalocyanines derivatives, naphthalocyanine derivatives, or butadiene derivatives. Quinoline derivatives, such as, for example, dipyrazino[2,3-f:2′,3′-h]quinoxalinehexacarbonitrile, are also suitable.

Inorganic compounds, such as p-type Si and p-type SiC, can also be used, as can inorganic oxides, such as, for example, vanadium oxide (VOₓ), molybdenum oxide (MoOₓ) or nickel oxide (NiOₓ).

Particular preference is given to tertiary aromatic amines, as described, for example, in US 2008/0102311 A1, for example NPD from U.S. Pat. No. 5,061,569, TPD 232 and MTDATA from JP 4-308688. Preference is furthermore given to phthalocyanine derivatives, such as, for example, H₂Pc, CuPc, CoPc, NiPc, ZnPc, PdPc, FePc, MnPc, ClAlPc, ClGaPc, ClInPc, ClSnPc, Cl₂SiPc, (HO)AlPc, (HO)GaPc, VOPc, TiOPc, MoOPc, GaPc-O—GaPc.

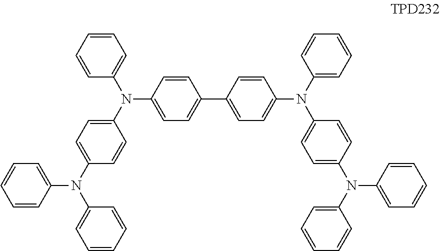

Particular preference is given to compounds which contain a plurality of units containing tertiary amines, such as, for example,

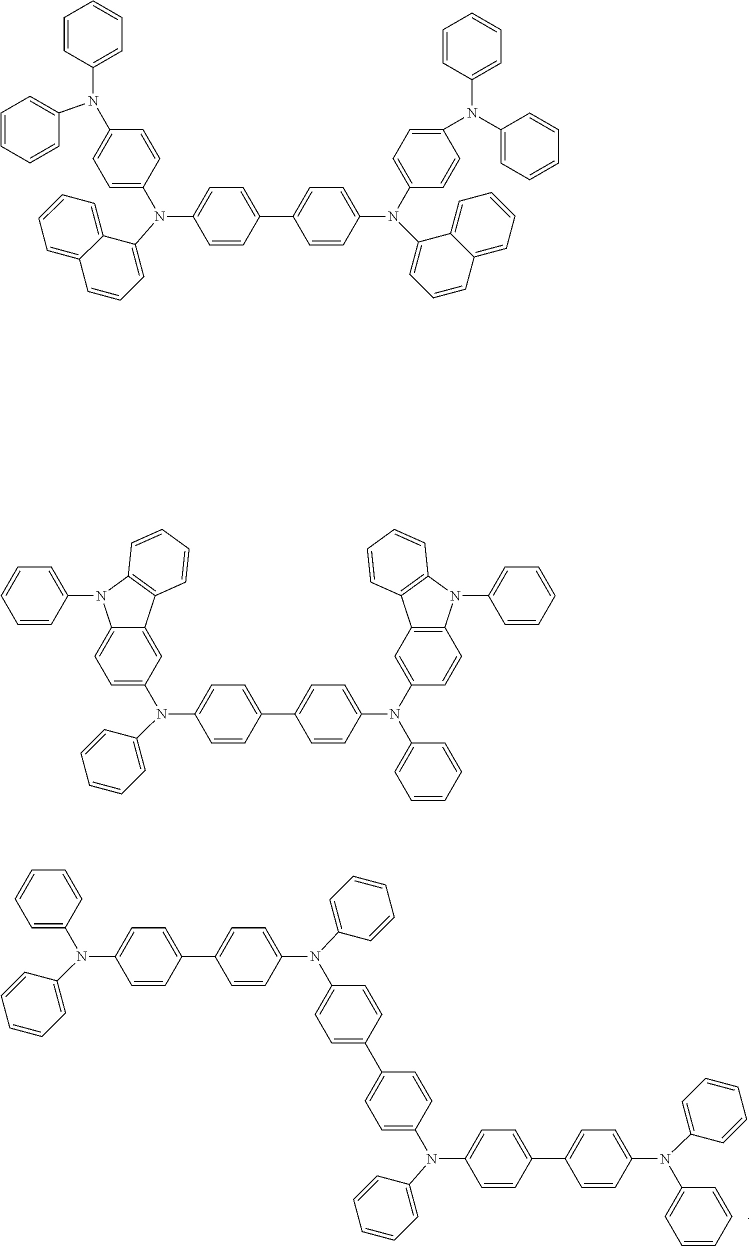

If the colour converter is present in the hole-transport layer or hole-injection layer, its concentration is preferably selected in the range from 1 to 30% by weight, preferably 3 to 20% by weight and particularly preferably 3 to 10% by weight, based on the weight of the corresponding layer.

As already explained, a barrier layer, which preferably does not comprise a colour converter, is, in accordance with an embodiment, provided between hole-transport layer and light-emitting layer. The barrier layer can be in the form of an electron-blocking layer or exciton-blocking layer. The materials used for an electron-blocking layer can be, for example, transition-metal complexes, for example Irppz, which is described in US 2003/0175553. Materials which can be used for exciton-blocking layers are substituted triarylamines, such as, for example, MTDATA or TDATA. Substituted triarylamines are described, for example, in US 2007-0134514 A1.

N-substituted carbazole compounds, such as, for example, TCTA, or heterocycles, such as, for example, BCP, are also suitable.

In accordance with a further embodiment, the organic light-emitting diode comprises an electron-transport layer, where the electron-transport layer comprises the colour converter.

The electron-transport layer can consist of an intrinsic material or comprise a dopant by means of which the conductivity of the layer is established. Materials which can be used for the electron-transport layer are per se all materials which are known as electron conductors to the person skilled in the art. Suitable compounds are, for example, metal complexes of quinoline oxides, as described, for example, in U.S. Pat. No. 4,885,211. Illustrative compounds are aluminium tris(8-hydroxyquinoline), magnesium bis(8-hydroxyquinoline), gallium oxinate or indium trisoxinate. Also suitable are butadiene derivatives, as are described, for example, in U.S. Pat. No. 4,356,429, or also benzoxazoles, triazines, anthracenes, tetracenes, fluorenes, spirofluorenes, dendrimers, tetracenes, for example rubrene derivatives, and 1,10-phenanthroline derivatives. Compounds of this type are described, for example, in JP 2003-115387, JP 2004-311184, JP 2001-267080 and WO 2002/043449. Also suitable are silacyl-cyclopentadiene derivatives, as described in EP 1 480 280, EP 1 478 032 and EP 1 469 533, pyridine derivatives, as known, for example, JP 2004-200162, phenanthrolines, for example BCP and Bphen. A plurality of phenanthrolines connected via biphenyl or other aromatic groups, as described in US 2007/0252517 A1, or phenanthrolines connected to anthracene, as known from US 2007-0122656 A1, can also be employed as materials for the electron-transport layer.

Preference is given to 2,9,10-substituted anthracenes (with 1- or 2-naphthyl and 4- or 3-biphenyl) or molecules which contain two anthracene units. Compounds of this type are described, (for example, in US 2008/0193796 A1.

Preference is likewise given to anthracene-benzimidazole derivatives, such as, for example,

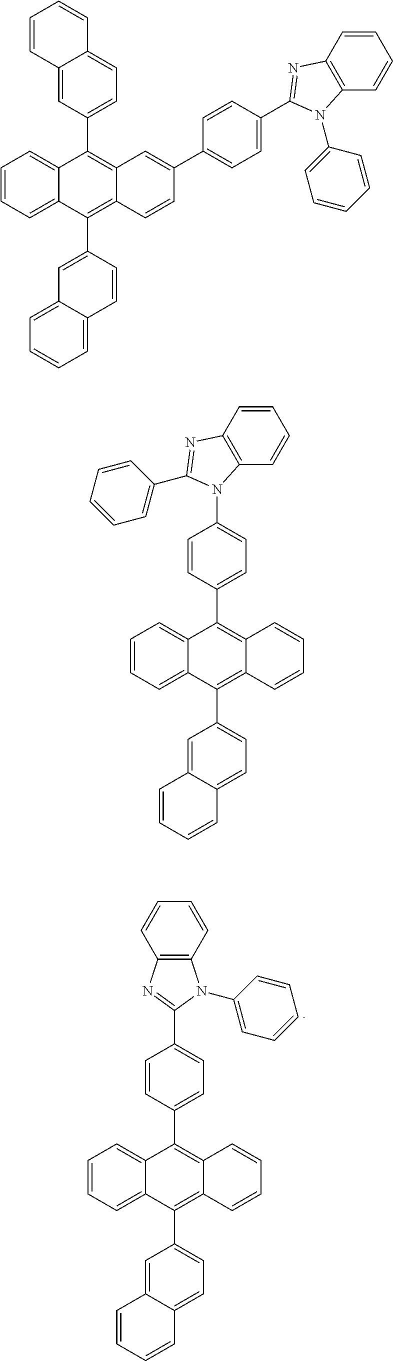

According to a further embodiment, the organic light-emitting diode comprises an electron-injection layer, where the colour converter is arranged in the electron-injection layer. Conventional materials known to the person skilled in the art can likewise be used for the electron-injection layer. These materials have a high dielectric constant. Suitable for this purpose are, for example, alkali-metal or alkaline-earth metal fluorides, but also the corresponding oxides, for example LiF, Li₂O, CaF₂, MgO, NaF, etc. It is likewise possible to employ alkali-metal complexes, alkaline-earth metal complexes, rare-earth metals (Sc, Y, Ce, Th, Yb), rare-earth metal complexes, rare-earth metal compounds (preferably YbF₃, ScF₃, TbF₃) or the like.

Likewise suitable are heterocyclic organic compounds, such as, for example, 1,10-phenanthroline derivatives, benzimidazoles, thiopyran dioxides, oxazoles, triazoles, imidazoles or oxadiazoles. For the use of five-membered rings containing N, such as, for example, oxazoles, thiazoles, oxadiazoles, thiadiazoles, triazoles, inter alia, see US 2008/0102311 A1. Preferred compounds are the following:

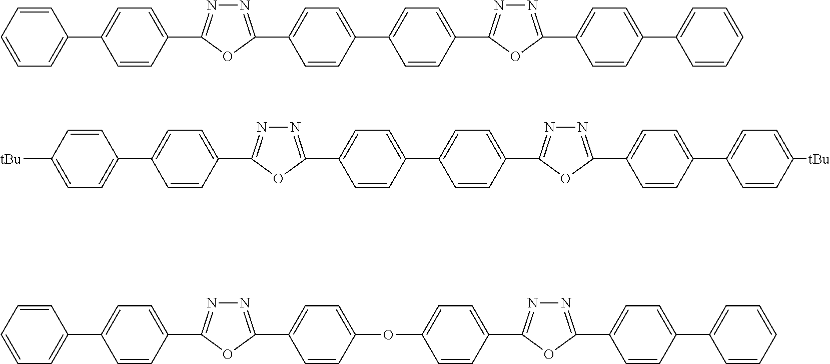

It is also possible to employ organic compounds, such as fluorenones, fluorenylidinemethane, perylenetetracarbonic acid, anthraquinonedimethanes, diphenoquinones, anthrones and anthraquinonediethylenediamines, for example

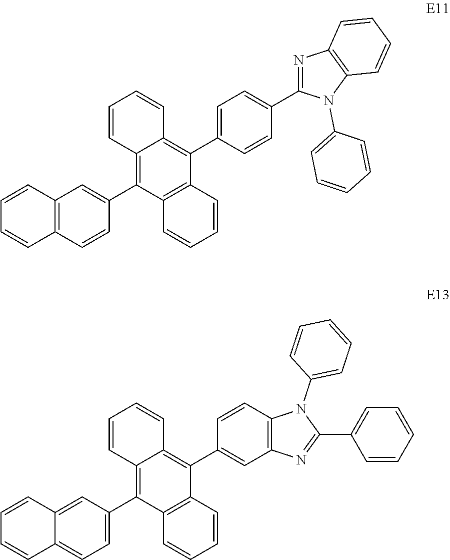

The layer thickness of a layer of this type is preferably between 1 and 10 nm.

Preferred materials for the anode are metal oxides, such as, for example, indium tin oxide (ITO), indium zinc oxide (IZO), tin oxide (SnO, “NESA”), ZnO, InO, aluminium zinc oxide (AIZnO) or other metal oxides, such as, for example, Al- or In-doped zinc oxide, magnesium indium oxide or nickel tungsten oxide. It is also possible to use metal nitrides, such as, for example, gallium nitride, and metal selenides, such as, for example, zinc selenide, and metal sulfides, such as, for example, zinc sulfide. Likewise suitable are electrically conductive polymers, such as, for example, polythiophene or polypyrrole.

If the anode does not have to be transparent, it is possible to use conductor materials such as, for example, Au, Ir, Mo, Pd, Pt, Cu, Ag, Sn, C, Al, V, Fe, Co, Ni, W, also as a mixture of two or more elements or compounds, for example In/Cu.

The cathode may be transparent, opaque or reflective. Metals, alloys or electrically conductive compounds having a work function of less than 4.0 eV, such as, for example, Ba, Ca, Sr, Yb, Ga, Cd, Si, Ta, Sb, Zn, Mg, Al, In, Li, Na, Cs, Ag, but also mixtures of two or more elements, for example Mg/Al or Al/Li or Al/Sc/Li or Mg/Ag alloys, or metal oxides, such as, for example, ITO or IZO, are usually employed.

An Mg:Al cathode with ITO layer on top is described in U.S. Pat. No. 5,703,436, U.S. Pat. No. 5,707,745, U.S. Pat. No. 6,548,956 B2, U.S. Pat. No. 6,576,134 B2. An Mg:Ag alloy is described by U.S. Pat. No. 4,885,221.

It is also possible to use materials other than those mentioned here. Suitable materials are known to the person skilled in the art.

According to an embodiment, at least one of the electrodes is designed to be reflective. Light emitted by the light-emitting layer in the direction of the reflective electrode is then reflected and then passes through the optoelectronic device again and then leaves it on the opposite side. The reflected light may correspond directly to the light emitted by the light-emitting layer. However, it is also possible for the reflected light to Correspond at least in part to the light emitted by the colour converter.

According to a preferred embodiment, the opto-electronic device, in particular the OLED, is mirrored on the cathode side, i.e. the light emitted by the electroluminescent layer is reflected on the cathode side and leaves the opto-electronic device, in particular OLED, on the anode side.

This embodiment is particularly preferred if the opto-electronic device is in the form of an OLED. The colour converter is then preferably arranged in the electron-transport layer or electron-injection layer or in both of these layers. The light emitted by the light-emitting layer then passes through the electron-transport layer or, if provided, the electron-injection layer, in the direction of the cathode. A colour converter is provided in at least one of these layers. The light of the first wavelength or from the first wavelength range emitted by the light-emitting layer results in the emission of light of a second wavelength or in a second wavelength range. This light emitted by the colour converter is reflected by the cathode and therefore leaves the OLED on the anode side. The light emitted by the light-emitting layer directly on the anode side thus mixes with the light reflected by the cathode. If the light emitted by the light-emitting layer is selected, for example, in the blue region and the light emitted by the colour converter and reflected by the cathode is selected in the orange region, the two colours can add up to white light. The choice of the electroluminescent organic material and the colour converter enables the generation per se of any desired colour, which is emitted by the OLED on the anode side.

As already explained, the organic light-emitting diode according to the invention can be used, for example, as lighting element for room lighting. According to a further embodiment, use as display element is also possible, where, for example, a logo or a symbol is displayed on a background of a different colour. Displays of this type can, for example, mark escape routes or exits. Such an embodiment of the organic light-emitting diode according to the invention is distinguished by the fact that the light-emitting diode is divided into at least two area sections, where at least two area sections emit light having a different wavelength spectrum. It is conceivable here for, for example, the background to be formed by the light emitted by the light-emitting layer which comprises the electroluminescent organic material, while the writing or the symbol arranged on the background is displayed by the light emitted by the colour converter. However, the opposite case is also conceivable, i.e. the background is formed by the light emitted by the colour converter, while the symbol arranged on the background or the writing is displayed by the light emitted by the electroluminescent organic material arranged in the light-emitting layer. Finally, it is also conceivable for both the background and also the symbol arranged on the background or the writing to be generated by light generated by a colour converter, but where different colour converters which emit light of different wavelength are selected for background and the symbol displayed on the background or the writing, so that a contrast is generated between background and a symbol arranged on the background or writing. The light-emitting layer here can be divided into various sections, so that, for example, a first section emits light which is utilised for the display of the background, while a second section emits light which is utilised for the display of the symbol or writing. In this way, for example, the brightness of the sections can be regulated individually with the aid of the applied voltage.

According to a preferred embodiment, at least a part-amount of the at least two area sections has a common light-emitting layer. the light-emitting layer, which comprises the electroluminescent organic material, can then be produced in a single working step, with no structuring of the light-emitting layer being necessary. This continuous light-emitting layer then emits light of substantially homogeneous light intensity over its entire area, where the light intensity drops substantially homogeneously over the entire area over the lifetime of the organic light-emitting diode. A layer which comprises the colour converter is then applied in sections, directly or indirectly, to the continuous common light-emitting layer, where the colour converter can be selected to be different for different area sections.

The organic light-emitting diode according to the invention can also be designed in such a way that it can be used, for example, in displays. To this end, the organic light-emitting diode is designed in such a way that it can be addressed individually and can, for example, be switched on or off. To this end, it may be provided, in accordance with an embodiment, that the light-emitting diode comprises an active matrix as substrate. A substrate of this type can be produced in a conventional manner known to the person skilled in the art by, for example, building up corresponding transistors and conduction tracks on a silicon wafer. It is likewise possible for switching elements of this type, for example in the form of thin-film transistors, to be applied to a glass sheet or a plastic film. With the last-mentioned embodiment in particular, it is possible to produce displays relatively inexpensively in this way, which can also, for example, be designed to be flexible in the case of the use of a plastic film.

The invention furthermore relates to a process for the production of the opto-electronic device described above, where the latter is preferably in the form of an OLED. The procedure here can per se be the same as is usual in the production of opto-electronic devices of this type, in particular of organic light-emitting diodes, but where a colour converter is added to at least one of the layers which is present besides the light-emitting layer which comprises an electroluminescent organic material. The concentration of the colour converter here is selected in accordance with the desired result. The concentration of the colour converter can be selected to be sufficiently high that the light emitted by the light-emitting layer is absorbed completely, so that essentially only light emitted by the colour converter is visible from the outside. However, it is also possible to select the concentration in such a way that only some of the light emitted by the light-emitting layer is absorbed by the colour converter, so that mixed colours between the light emitted by the light-emitting layer and the light emitted by the colour converter are generated.

The production of the opto-electronic device can be carried out in a conventional manner. For example, it is possible firstly to provide a substrate, which can optionally be provided with supply and discharge lines and switching elements for addressing individual pixels. As already described above, a substrate of this type can be, for example, a semiconductor material, for example a silicon wafer. However, it may also be an electronically inert material, for example a ceramic material, a glass or a plastic film, where supply and discharge lines for the current supply of the electrodes are arranged on the substrates. Depending on the application in which the organic light-emitting diode according to the invention is to be employed, the substrate can be opaque or transparent. Conductor tracks and optionally switching elements for addressing the organic light-emitting diode are then arranged on the substrate. To this end, it is possible to use conventional techniques, as are known from the production of microelectronic components. The electrode of the light-emitting diode can optionally be applied to the substrate at the same time as the provision of supply and discharge lines. To this end, for example, corresponding sections can be defined by shadow masks, where, for example, a metal is subsequently applied by vapour deposition, so that the shape and size of the electrodes is determined by the shadow mask. It is likewise possible firstly to apply a metal layer, which is then covered with a photosensitive layer, which is developed after section-wise exposure. The sections of the metal layer uncovered after the development can then be etched, for example using a plasma. However, it is also possible to apply the electrodes by printing, for example. The individual rayers of the organic light-emitting diode are subsequently applied in a conventional manner, to which end conventional techniques are used, as are known to the person skilled in the art from the production of electronic components of this type. The individual layers can be applied by vapour deposition and optionally structured, or also defined by printing techniques. No particular restrictions of the known production processes are necessary here per se. Conventional cleaning steps or planarisation steps can also be carried out, if necessary, between the individual production steps.

According to a preferred embodiment, at least individual layers of the light-emitting diode are produced using a solvent-based process, where, according to a further embodiment, water is used as solvent. The components of the layer in question are dissolved or dispersed in a suitable solvent, for example water, alcohol or another organic solvent, and then applied to the substrate by spin coating. To this end, the substrate is set in rotation around a vertical axis, and the solution of the layer components in question are placed onto the rotating substrate. Excess solution is spun off the surface of the substrate by the centrifugal force, giving a thin film having a defined layer thickness. The solvent can be removed, so that the layer in question solidifies. According to an embodiment, the layer may also be crosslinked, for example by a polymerisation reaction, and thus solidified.

Preferred processes for the production of an opto-electronic device are printing processes. Particular preference is given to printing processes selected from the group consisting of spin coating, ink-jet printing, screen printing, flexo printing, gravure printing and doctor-blade printing. Very particular preference is given to ink-jet printing.

According to a further embodiment of the present invention, further preferred printing techniques for the production of the opto-electronic device are dip coating, letterpress printing, roller printing, reverse-roller printing, offset lithography printing, web printing, spray coating, brush coating or pad printing and slot-die coating.

According to an embodiment, successive layers are produced using different solvents. This enables a very sharp separation between the layers, which in turn contributes to the generation of uniform luminosity, for example over the area of an OLED.

According to a further embodiment, the hole-transport layer is made from PEDOT or PANI which is doped with an acid, such as, for example, PSSH, where, according to an embodiment, an aqueous process is used in order to apply the layer to the substrate.

The invention furthermore relates to the use of the opto-electronic devices according to the invention, in particular if these are in the form of OLEDs, in lighting devices or in displays. The term “lighting devices” here encompasses, for example, general lighting and also backlighting, for example of LCDs. In the case of use in displays, it is preferred for the light-emitting diodes to be provided in the primary colours red, green and blue.

The invention is described in greater detail below with reference to working examples and with reference to the attached drawing, but without being restricted thereby.

The individual figures here show:

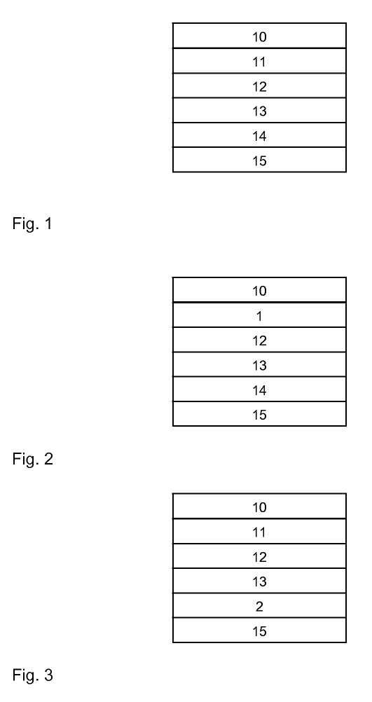

FIG. 1: the structure of an SMOLED in accordance with the prior art;

FIG. 2: the structure of a first embodiment of an OLED according to the invention;

FIG. 3: the structure of a second embodiment of an SMOLED according to the invention;

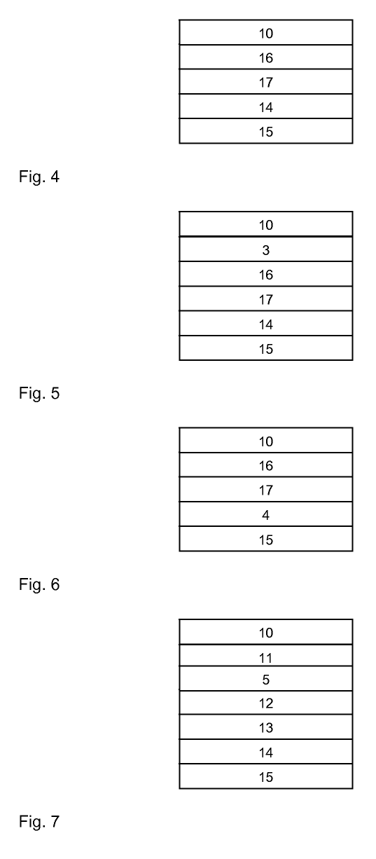

FIG. 4: the structure of a PLED in accordance with the prior art;

FIG. 5: the structure of a third embodiment of a PLED according to the invention;

FIG. 6: the structure of a fourth embodiment of a PLED according to the invention;

FIG. 7: the structure of a fifth embodiment of an SMOLED according to the invention;

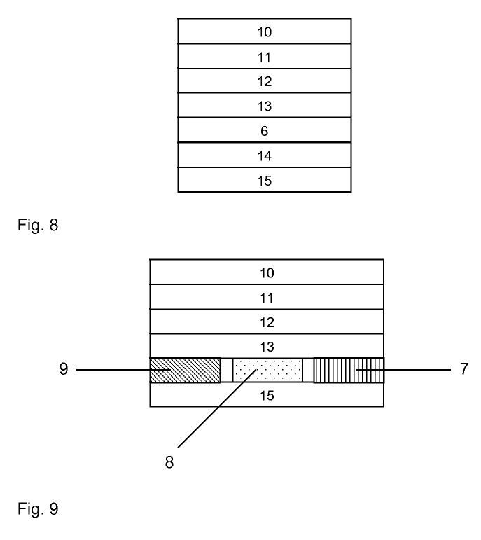

FIG. 8: the structure of a sixth embodiment of an SMOLED according to the invention;

FIG. 9: the structure of a seventh embodiment of an OLED according to the invention;

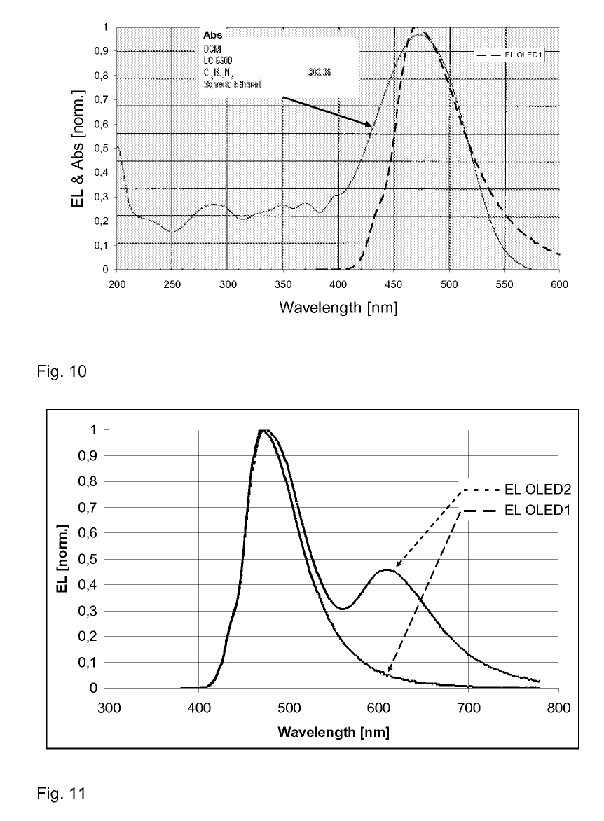

FIG. 10: a diagram in which the electroluminescence of OLED1 is compared with the absorption by DCM;

FIG. 11: a diagram in which the electroluminescence of OLED1 and OLED2 is compared;

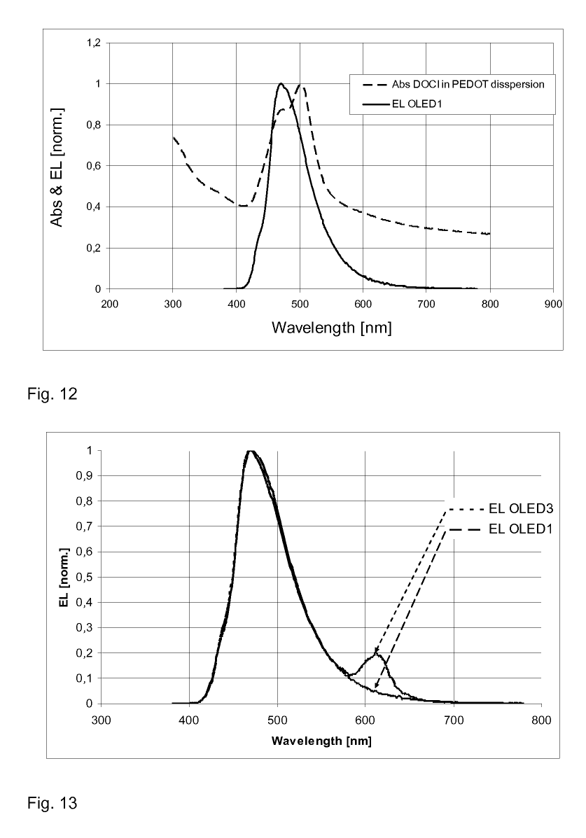

FIG. 12: a diagram in which the electroluminescence of OLED1 is compared with the absorption by DOCI dispersed in PEDOT;

FIG. 13: a diagram in which the electroluminescence of OLED1 and OLED3 is compared.

FIG. 14: structure of an embodiment of an OLEFT according to the invention, where a layer which comprises at least one colour converter is located between the drain and source electrodes.

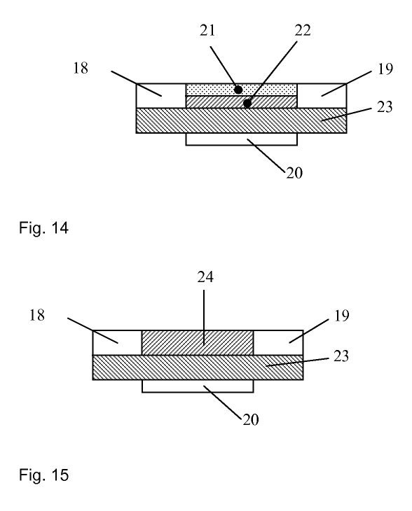

FIG. 15: structure of an embodiment of an OLEFT according to the invention, where the colour converter is doped directly into the emission layer (EML).

FIG. 1 shows a section through a structure of an OLED as is known from the prior art. Firstly, an electron-transport layer (ETL) 11 is arranged on a cathode 10 and is followed by a light-emitting layer (EML) 12. A hole-transport layer (HTL) 13 is arranged on the opposite side of the light-emitting layer and is followed by a hole-injection injection (HIL) 14. The hole-injection layer 14 is followed by an anode 15.

FIG. 2 shows a section through the stack of an SMOLED (small molecule organic light-emitting device) according to the invention. In this embodiment, the cathode 10 is followed by an electron-transport layer 1, where the latter is build up from a mixture of en electron-transporting material and a colour converter. This layer 1 is followed by a light-emitting layer (EML) 12, a hole-transporting layer (HTL) 13, a hole-injection layer 14 and an anode. The light emitted by the light-emitting layer (EML) 12 is at least partly converted by the colour converter present in layer 1 into light which has a greater wavelength than the light emitted by the light-emitting layer (EML) 12. The electron-transporting layer (ETM) 1 preferably acts as hole-blocking layer and particularly preferably both as hole-blocking layer and also as exciton-blocking layer with respect to the light-emitting layer (EML) 12.

In this device, the cathode 10 is preferably designed to be reflective. A proportion of the light emitted by the light-emitting layer 12 leaves the device through the transparent anode 15. Another proportion passes through layer 1 and excites the colour converter present in layer 1, which then emits light of greater wavelength. Some of the light emitted by the colour converter leaves the device in the direction of the transparent anode 15. Another part is reflected by the reflective cathode 10, so that it likewise leaves the OLED through the transparent anode 15. Light which has been emitted by the electroluminescent layer 12, but has not been absorbed by the colour converter, is reflected by the cathode 10 and passes through layer 1 again, where it can again excite the colour converter and induce the emission of light having a greater wavelength, thus increasing the quantum yield of the colour converter. In this embodiment, the SMOLED emits a mixed light which is composed of the light emitted directly by the electroluminescent layer 12 and the light emitted by the colour converter.

FIG. 3 shows the structure of a further preferred embodiment of an SMOLED according to the invention. In this case, the colour converter is arranged in a layer 2 which is directly adjacent to the transparent anode 15. In this embodiment, the reflective cathode 10 is thus followed by an electron-transporting layer (ETL) 11, a light-emitting layer (EML) 12, and a hole-transporting layer (HTL) 13. A layer 2 which comprises a hole-injecting material and a colour converter is arranged between HTL 13 and anode 15. The colour converter absorbs at least part of the light emitted by the light-emitting layer (EML) 12 and emits light of a greater wavelength. Light from the electroluminescent layer 12 which is emitted in the direction of the reflective cathode 10 is reflected by the cathode 10 and then passes through layer 2, which comprises the colour converter. Given a corresponding choice of the colour converter, the SMOLED in this embodiment can be designed in such a way that it essentially only emits light which is emitted by the colour converter. The hole-transporting material of the hole-transporting layer HTL 13 preferably also acts as electron-blocking material and further preferably also as exciton-blocking material with respect to the light-emitting layer (EML) 12.

FIG. 4 shows the structure of a PLED (polymer organic light-emitting device), as is realised in the prior art. The cathode 10 is followed by a light-emitting layer (LEP) 16, which comprises a light-emitting polymer. On the side opposite the cathode 10, the light-emitting layer 16 is followed by an interlayer 17, which is in turn followed by a hole-injecting layer (HIL) 14. The hole-injecting layer (HIL) 14 is followed by the anode 15.

FIG. 5 shows the structure of a PLED according to the invention. The cathode 10 is followed by a layer 3 which comprises both an electron-transporting material and also a colour converter. This layer 3 is followed by a light-emitting layer (LEP) 16 which comprises a light-emitting polymer. Analogously to FIG. 4, this is followed by an interlayer 17, a hole-injecting layer (HIL) 14 and a transparent anode 15. At least part of the light emitted by the light-emitting layer (LEP) 16 is converted by the colour converter into light having a longer wavelength. The electron-transporting layer preferably acts as hole-blocking layer and further preferably also as exciton-blocking layer with respect to the light-emitting layer (LEP) 16.

FIG. 6 shows a further embodiment of a PLED according to the invention. A light-emitting layer LEP 16 which comprises a light-emitting polymer is arranged on the cathode 10. This is followed firstly by an interlayer 17 and then a layer 4 which comprises a hole-injecting material and a colour converter. The colour converter converts at least part of the light emitted by the light-emitting layer (LEP) 16 into light having a longer wavelength. The interlayer 17 preferably acts as electron-blocking layer and further preferably also as exciton-blocking layer with respect to the light-emitting layer.

FIG. 7 shows the structure of a further embodiment of the SMOLED according to the invention. A cathode 10 is followed firstly by an electron-transporting layer (ETL) 11 and then a layer 5. Layer 5 comprises a mixture of an electron-transporting material and a colour converter. Layer 5 is followed by a light-emitting layer (EML) 12, a hole-transporting layer (HTL) 13, a hole-injecting layer (HIL) 14 and an anode 15. The electron-transporting material present in layer 5 preferably acts as hole-blocking layer and further preferably also as exciton-blocking layer with respect to the light-emitting layer.

FIG. 8 shows a section through a further preferred embodiment of an SMOLED according to the invention. A cathode 10 is followed firstly by an electron-transporting layer (ETL) 11, followed by a light-emitting layer (EML) 12 and a hole-transporting layer (HTL) 13. The hole-transporting layer (HTL) 13 is followed by a layer 6 which comprises a mixture of a colour converter and a hole-injecting material or a hole-transporting material or a mixture of all three of these components. The hole-transporting layer (HTL) 13 preferably also acts as electron-blocking layer and further preferably also as exciton-blocking layer with respect to the light-emitting layer (EML) 12.

FIG. 9 shows a section through a device according to the invention which is suitable, for example, for emitting white light. The cathode 10 is followed firstly by a common electron-transporting layer (ETL) 11 and a common light-emitting layer (EML) 12, which emits, for example, blue light. The light-emitting layer (EML) 12 is followed by a common hole-transporting layer (HTL) 13. A section 7 which comprises a hole-injecting material is arranged on the common hole-transporting layer (HTL) 13. The blue light emitted by the light-emitting layer (EML) 12 exits unchanged through this section 7 on the side of the anode 15. In section 8, the hole-injecting material is mixed with a first colour converter which absorbs the blue light from the light-emitting layer 12 and emits green light. A layer which, besides the hole-injecting material, also comprises a second colour converter is arranged in section 9. The second colour converter absorbs the blue light emitted by the light-emitting layer 12 and emits red light. The total colour emitted by the OLED can be tuned by adaptation of the areas of sections 7, 8 and 9.

FIG. 14 shows a section through a device according to the invention which represents an OLEFT, which comprises a drain 18, a source 19, a gate 20, a layer comprising the colour converter 21, a light-emitting layer (EML) 22 and a substrate 23.

FIG. 15 shows, analogously to FIG. 14, a section through a device according to the invention which represents an OLEFT. In contrast to the OLEFT depicted diagrammatically in FIG. 14, the colour converter here is doped directly into the light-emitting layer 24.

It should be pointed out that variations of the embodiments described in the present invention fall within the scope of this invention. Each feature disclosed in the present invention can, unless explicitly excluded, be replaced by alternative features which serve the same, an equivalent or a similar purpose. Each feature disclosed in the present invention should thus, unless stated otherwise, be regarded as an example of a generic series or an equivalent or similar feature.

All features of the present invention can be combined with one another in any manner, unless certain features and/or steps are mutually exclusive. This applies, in particular, to preferred features of the present invention. Equally, features of non-essential combinations can be used separately (and not in combination).

It should furthermore be pointed out that many of the features, and in particular those of the preferred embodiments of the present invention, are themselves inventive and should not merely be regarded as part of the embodiments of the present invention. For these features, independent protection may be sought additionally or alternatively to each invention currently claimed.

The teaching regarding technical action disclosed with the present invention can be abstracted and combined with other examples.

The invention is explained in greater detail by the following examples, without wishing to restrict it thereby.

### EXAMPLES

The following polymers were prepared by Suzuki coupling by the process described in WO03/048225:

### IL1:

Polymer IL1 is used as material for an interlayer and comprises the following monomers M1 and M2:

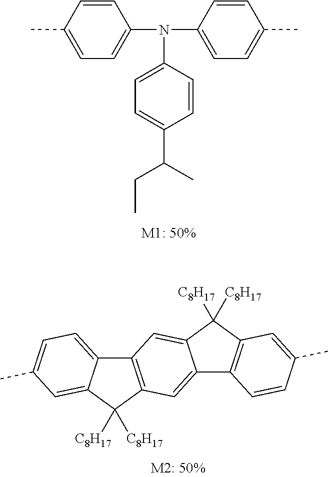

The molecular weight M_{w} of the resultant polymer IL1 is between 200,000 and 300,000 g/mol.

### LEP1

Polymer LEP1 was used as light-emitting polymer. The copolymer comprises the following monomers M3 to M6:

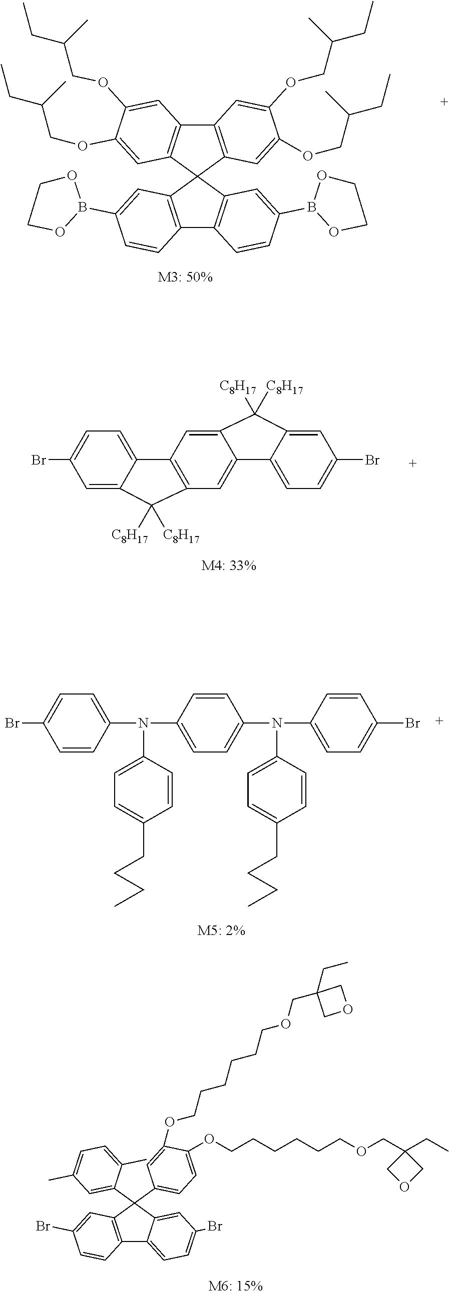

Monomer M6 contains oxetane groups for crosslinking of the material.

### ETM1

The electron-transporting material used was the following compound:

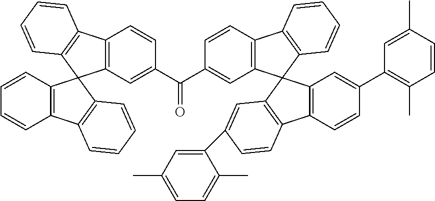

### Laser Dyes

The laser dyes employed were DCM, which is soluble in toluene, and DOCI, which is water-soluble. Both dyes were purchased from Lambda Physik, DE, and employed directly. The formulae of the compounds are shown below:

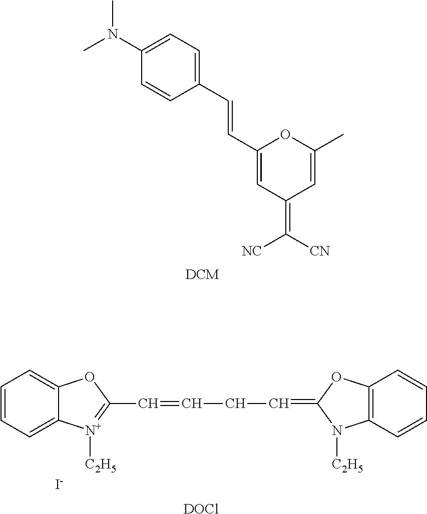

### Electronic Structure of IL1, LEP1 and ETM1

The electronic structure of IL1, LEP1 and ETM1 was investigated with the aid of quantum-chemical simulations in order to investigate the electron-blocking and exciton-blocking properties of IL1 compared with LEP1, and the hole-blocking and exciton-blocking properties of ETM1 compared with LEP1. The HOMO/LUMO of organic compounds can be calculated using the method described in WO 2008/011953, where the results are in good agreement with cyclic voltammetry measurements.

The calculation of the HOMO and LUMO was carried out in Gaussian 03W with the aid of time-dependent DFT (density function theory) using the same correction function B3PW91 and the same base set 6-31G(d). The values calculated were then calibrated with the aid of calibration factors determined by comparison of measured and calculated values of a number of selected molecules. The trimer M2-M1-M3 was used for the calculation for IL1, the trimer M3-M4-M3 was used for the calculation of the polymer backbone for LEP1, and the trimer M3-M5-M3 was used for the calculation of the emitter.

TABLE 1
Electronic structure of the compounds

| | | Homo corr. [eV] | Lumo corr. [eV] |
|---|---|---|---|
| Interlayer | M2-M1-M2 | −5.14 | −2.47 |
| LEP1 emitter | M3-M5-M3 | −4.89 | −2.29 |
| LEP1 backbone | M3-M2-M3 | −5.19 | −2.55 |
| ETL | ETM1 | −5.85 | −2.69 |

Table 1 shows the electronic structure, i.e. the HOMO or LUMO for ILA, LEP1 and ETM1. Interlayer IL1 has a higher LUMO than the backbone of LEP1, so that it acts as electron-blocking layer. In LEP1, emitter M5 also acts as hole trap in the polymer backbone, producing a narrow emission area which is arranged close to the emission layer. Compared with LEP1, ETM1 has a considerably lower HOMO and therefore acts as hole-blocking layer. Furthermore, it has a significantly larger band gap than the LEP1 backbone and the LEP1 emitter and therefore acts as exciton-blocking layer. If this knowledge is taken into account, the colour converter in ETM1 can only be excited optically or in other words can neither be excited electronically nor take up an exciton from LEP1 by exciton diffusion. The same also applies in the case where the colour converter is arranged in the buffer layer.

### Production of the OLED

### Example 1

### OLED1 (Prior Art)

The OLED1 shown in FIG. 4, which has a structure known from the prior art, was produced by a process having the following steps:
1. Firstly, a layer of PEDOT (Baytron P AI 4083) with a thickness of 80 nm is applied to an ITO-coated glass substrate by spin coating. This layer acts as hole-injection layer.
2. In a glove box, a layer of IL1 with a thickness of 20 nm is applied by spin coating. To this end, a solution in toluene with a concentration of 0.5% by weight is used.
3. Layer IL1 is then cured for one hour in the glove box at 180° C.
4. In order to produce the LEP layer, firstly a first solution of LEP1 with a concentration of 1% by weight in toluene is prepared. Using the first solution, the rotational speed for the production of a layer thickness of 65 nm is determined. Furthermore, a second solution of 1% by weight of the photoinitiator 4-[(2-hydroxytetradecyl)oxyl]phenyl}-phenyl-iodonium hexafluoroantimonate) (OPPI) in toluene is prepared. First and second solution are then mixed in a ratio of 10 ml to 0.05 ml, and the mixture is applied to the substrate by spin coating at the previously determined rotational speed, so that a layer thickness of 65 nm is obtained. For curing, the film is firstly irradiated with UV light (360 nm) for 5 seconds and then heated at 100° C. for 1 minute. The process is described in general terms in DE 10 2004 009355 A1.
5. The device is heated at 180° C. for a further 10 minutes.
6. A Ba/Al cathode is then applied to the layer by vapour deposition, where the layer thicknesses are 3 nm and 150 nm.
7. Finally, the layer stack is encapsulated.

### Example 2

### OLED2 (According to the Invention)

The OLED according to the invention shown in FIG. 5 is produced by a process having the following steps.

The steps described in the case of the production of OLED1 are repeated, but the layer thickness of the LEP1 layer is reduced to 35 nm.
5. A layer of DCM/ETM1 with a thickness of 30 nm is then applied by spin coating by applying a 2.5% by weight of a solution of a mixture of DCM/ETM1 (1:4) in toluene.
6. The device is then cured at 180° C. for 10 minutes;
7. a Ba/Al cathode is then applied to the light-emitting layer by vapour deposition, where the layer thicknesses are 3 nm and 150 nm;
8. Finally, the layer stack is encapsulated.

### Example 3

### OLED3

The OLED according to the invention shown in FIG. 6 is produced by a process having the following steps:

80 nm of a mixture of PEDOT (Baytron P AI 4083) and DOCI (0.1-0.5% by weight) are applied as hole-injection layer to an ITO-coated glass substrate by spin coating.

Steps 2 to 7 are then carried out as described in Example 1.

### Example 4

### Characterisation and Comparison of the OLEDs

Electroluminescence spectra of the OLEDs produced as described above were recorded and the external quantum yield was determined.

FIG. 10 shows a comparison of the electroluminescence spectrum of OLED1 and an absorption spectrum of DCM in ethanol, which is provided by Lambda Physik. A very good overlap of the two spectra is evident. The absorption maximum of the colour converter DCM is close to the emission maximum of the light-emitting layer. The DCM should therefore be able to absorb the light emitted by the light-emitting layer and convert it into light having greater wavelength.

In FIG. 11, the electroluminescence spectrum of OLED1 is compared with the corresponding spectrum of OLED2. The second peak at a wavelength of about 612 nm corresponds to a fluorescence emission of DCM. This corresponds to a fraction of the light emitted by the light-emitting layer which has been converted into light of a longer wavelength by the colour converter DCM.

In FIG. 12, the electroluminescence spectrum of OLED1 is compared with the absorption spectrum of a dispersion of DOCI (0.2% by weight) in PEDOT. Very good overlap of the spectra is evident. The absorption maximum of the DOCI is close to the emission maximum of the light-emitting layer. The DOCI should therefore be able efficiently to absorb the light emitted by the light-emitting layer and convert it into light having greater wavelength.

FIG. 13 shows a comparison of the electroluminescence spectra of OLED1 and OLED3. The second peak at a wavelength of about 620 nm corresponds to a fluorescence emission of the DOCI. This peak arises through absorption of the light emitted by the light-emitting layer by the DOCI and a corresponding emission at greater wavelength. Since DOCI has only limited solubility in PEDOT, only a small proportion of the light emitted by the light-emitting layer is converted into light of a greater wavelength.

The examples show that light emitted by the light-emitting layer of an OLED can be converted into light having a greater wavelength by a colour converter using the opto-electronic device according to the invention. Tuning of the light emitted by the opto-electronic device according to the invention can be achieved, for example, by adaptation of the thickness of the layer which comprises the colour converter.

1-18. (canceled)

19. An opto-electronic device comprising at least two electrodes and at least one light-emitting layer, arranged between the electrodes, which comprises an electroluminescent organic material which emits light of a first wavelength or having a first wavelength spectrum, wherein a layer which comprises at least one colour converter is arranged between at least one of the at least one light-emitting layer and at least one electrode.

20. The opto-electronic device of claim 19, wherein the colour converter is a compound which absorbs light from the first wavelength spectrum and emits light having a second wavelength spectrum.

21. The opto-electronic device of claim 19, wherein at least one electrode is designed to be reflective.

22. The opto-electronic device of claim 19, wherein the at least two electrodes form a cathode and an anode, where the at least one layer which comprises the at least one colour converter is arranged between cathode and light-emitting layer.

23. The opto-electronic device of claim 19, wherein the opto-electronic device is an organic light-emitting diode (OLED).

24. The opto-electronic device of claim 23, wherein the at least one layer of the OLED which comprises the at least one colour converter is selected from the group of electron-injection layers, electron-transport layers, electron-blocking layers and exciton-blocking layers.

25. The opto-electronic device of claim 19, wherein the opto-electronic device is an organic light-emitting electrochemical cell (OLEC).

26. The opto-electronic device of claim 25, wherein at least one layer of the OLEC which comprises the at least one colour converter is selected from the group of hole-injection layers and electron-injection layers.

27. The opto-electronic device of claim 25, wherein the light-emitting layer of the OLEC comprises at least one colour converter.

28. The opto-electronic device of claim 19, wherein the opto-electronic device is an organic light-emitting field-effect transistor (OLEFT).

29. The opto-electronic device of claim 28, wherein at least one layer of the OLEFT which comprises the at least one colour converter is a dielectric layer.

30. The opto-electronic device of claim 19, wherein the light-emitting layer of the OLEFT comprises at least one colour converter.

31. A process for producing the opto-electronic device of claim 19, wherein an opto-electronic device having at least two electrodes and at least one light-emitting layer arranged between the at least two electrodes is produced in a conventional manner, wherein at least one further layer which comprises a colour converter is arranged between the at least one electrode and the at least one light-emitting layer.

32. The process of claim 31, wherein at least one layer is applied in the liquid phase.

33. The process of claim 31, wherein at least one layer is applied in the aqueous phase.

34. The process of claim 31, wherein the at least one further layer is a hole-transport or hole-injection layer.

35. The process of claim 31, wherein the at least one further layer is a hole-transport or hole-injection layer comprising PEDOT and/or PANI.
